(19) United States
(12) Patent Application Publication
(10) Pub. No.: US 2025/0357693 A1
(43) Pub. Date: Nov. 20, 2025

(54) CONNECTOR ASSEMBLY AND CONNECTOR HOUSING

(71) Applicant: Bellwether Electronic Corp., Taoyuan City (TW)

(72) Inventors: Jimmy Enrique ACERA, Taoyuan City (TW); Chih-Ming TSAI, Taoyuan City (TW)

(21) Appl. No.: 19/179,600

(22) Filed: Apr. 15, 2025

Related U.S. Application Data
(60) Provisional application No. 63/647,080, filed on May 14, 2024.
(60) Provisional application No. 63/665,269, filed on Jun. 28, 2024.

(51) Int. Cl. H01R 13/20; H01R 13/631; H01R 13/74

(52) U.S. Cl. CPC H01R 13/20; H01R 13/6315; H01R 13/748

(57) ABSTRACT

A connector assembly comprises: a socket comprising: a plurality of socket connectors; a socket housing covering the socket connectors and comprising a locking hole; and a limiting element disposed in the locking hole of the socket housing, and the limiting element comprising a first floating space in the locking hole; a connection panel having a first opening, and the socket housing being fixed to the connection panel; and a screw comprising a screw head and a screw pin, the screw pin passing through the first opening of the connection panel and being locked to the limiting element, in which the screw pin has a second floating space in the first opening.

### CROSS-REFERENCE TO RELATED APPLICATION

This application claims priority to U.S. Provisional Application Ser. No. 63/647,080 filed May 14, 2024, and U.S. Provisional Application Ser. No. 63/665,269 filed Jun. 28, 2024, the disclosures of which are incorporated herein by reference in their entireties.

### BACKGROUND

Nowadays, due to the increasing performance requirements of servers in data processing and computing systems, the stability and convenience of connectors have become crucial. A busbar connector is a connection element that can be used to connect a busbar to other electronic devices or systems. It can be used for high power transmission to ensure stable and reliable power connection. It is commonly found in server racks and power distribution systems. The main function of the busbar connector is to reliably connect these busbars to the power input terminals of the equipment (such as power supplies, servers, etc.).

Racks for electronic equipment, such as racks equipped with servers, are primarily used to support the equipment and provide power connections. When the electronic equipment in the rack is operating under high processing load or high power consumption, it may draw a lot of power from the connector, which may cause potential problems such as poor power delivery if the connector plug and socket are not properly connected. Therefore, a high-performance connector assembly is needed to solve the above potential problems.

### SUMMARY

The disclosure provides a connector assembly comprising: a socket comprising: a plurality of socket connectors; a socket housing covering the socket connectors and comprising a locking hole; and a limiting element disposed in the locking hole of the socket housing, and the limiting element comprising a first floating space in the locking hole; a connection panel having a first opening, and the socket housing being fixed to the connection panel; and a screw comprising a screw head and a screw pin, the screw pin passing through the first opening of the connection panel and being locked to the limiting element, in which the screw pin has a second floating space in the first opening.

In some embodiments, connector assembly further includes: a plug configured to be coupled or connected to a socket, wherein the plug has a plug housing and a plurality of conductive terminals located in the plug housing, wherein the conductive terminals pass through the connection panel and are respectively connected to the socket connectors of the socket.

In some embodiments, the connection panel has a second opening separated from the first opening, wherein the conductive terminal and the guide post of the plug housing pass through the second opening of the connection panel, wherein the second opening is larger than the first opening.

An embodiment of the present disclosure provides a connector housing, comprising a housing having a locking hole; a connection panel having a first opening; and a limiting mechanism having two ends to clamp the connection panel and at least a portion of the housing between the two ends; wherein the limiting mechanism can move relative to the housing within a first preset range, and/or the limiting mechanism can move relative to the connection panel within a second preset range.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a connector assembly, in accordance with some embodiments of the present disclosure.

FIG. 2A is a perspective view of a conductive terminal structure, in accordance with some embodiments of the present disclosure.

FIG. 2B is a side view of a conductive terminal structure, in accordance with some embodiments of the present disclosure.

FIG. 3A and FIG. 3B are perspective views of a conductive terminal structure and a conductive strip group, in accordance with some embodiments of the present disclosure.

FIG. 4 is a perspective view of a housing of a connector, in accordance with some embodiments of the present disclosure.

FIG. 5A is a perspective view of a conductive terminal structure and a housing, in accordance with some embodiments of the present disclosure.

FIG. 5B is a cross-sectional view of a conductive terminal structure and a housing, in accordance with some embodiments of the present disclosure.

FIG. 6A is a perspective view of a conductive strip assembly and a socket, in accordance with some embodiments of the present disclosure.

FIG. 6B is a cross-sectional view of a conductive strip assembly and a socket, in accordance with some embodiments of the present disclosure.

FIG. 7 is a perspective view of a socket and a connection panel, in accordance with some embodiments of the present disclosure.

FIG. 8 is a perspective view of a washer and a screw, in accordance with some embodiments of the present disclosure.

FIG. 9 is a perspective view of a connection panel, in accordance with some embodiments of the present disclosure.

FIG. 10 is a cross-sectional view of a connection panel and a socket, in accordance with some embodiments of the present disclosure.

FIG. 11A is a perspective view of a socket and a plug, in accordance with some embodiments of the present disclosure.

FIG. 11B is a perspective view of a conductive structure of a plug and a circuit board, in accordance with some embodiments of the present disclosure.

FIG. 11C is a perspective view of a plug, in accordance with some embodiments of the present disclosure.

FIG. 12 is a perspective view of a connector assembly, in accordance with some embodiments of the present disclosure.

FIG. 13 is a perspective view of a conductive terminal structure, in accordance with some embodiments of the present disclosure.

FIG. 14 is a perspective view of a conductive terminal structure and a conductive strip group, in accordance with some embodiments of the present disclosure.

FIG. 15 is a perspective view of a housing of a connector, in accordance with some embodiments of the present disclosure.

FIG. 16A, FIG. 16B, and FIG. 16C are perspective views of a conductive terminal structure and a housing, in accordance with some embodiments of the present disclosure.

FIG. 17 is a perspective view of a conductive strip assembly and a socket, in accordance with some embodiments of the present disclosure.

FIG. 18A and FIG. 18B are perspective views of a plug and a circuit board, in accordance with some embodiments of the present disclosure.

FIG. 19A and FIG. 19B are perspective views of a relative relationship among a plug, a socket and a connection panel, in accordance with some embodiments of the present disclosure.

### DETAILED DESCRIPTION

Various example embodiments will be described more fully hereinafter with reference to the accompanying drawings, in which some example embodiments are shown. The present disclosure may, however, be embodied in many different forms and should not be construed as limited to the example embodiments set forth herein. Rather, these example embodiments are provided so that this disclosure will be thorough and complete, and will fully convey the scope of the present disclosure to those skilled in the art. It is noted that, in accordance with the standard practice in the industry, various features are not drawn to scale. In fact, the dimensions of the various features may be arbitrarily increased or reduced for clarity of discussion.

The following disclosure provides many different embodiments or examples for implementing different features of the provided subject matter. Specific examples of components and arrangements are described below to simplify the present disclosure. These are, of course, merely examples, and are not intended to be limiting. For example, in the following description, the formation of a first feature above or on a second feature may include embodiments in which the first and second features are formed in direct contact, and may also include embodiments in which additional features may be formed between the first and second features so that the first and second features are not in direct contact. Furthermore, in various examples, the present disclosure may repeat reference numerals and/or letters. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Hereinafter, example embodiments will be explained in detail with reference to the accompanying drawings.

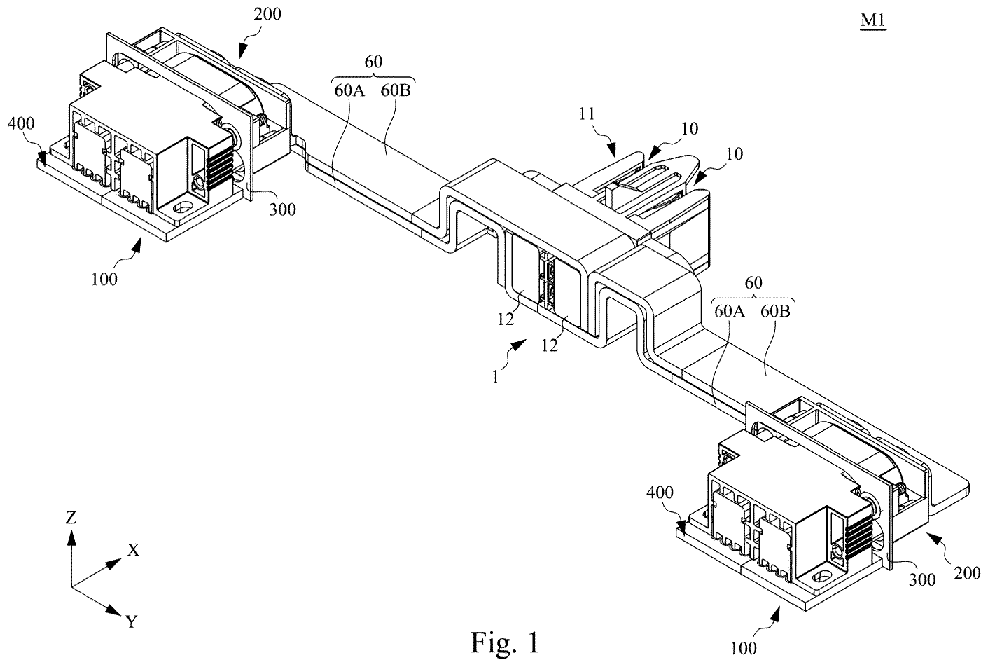

FIG. 1 is a perspective view of a connector assembly, in accordance with some embodiments of the present disclosure. The FIG. 1 shows a bus connector assembly, also called connector assembly M1. The connector assembly M1 may be a connection element that can connect a busbar to other electronic devices or systems. It is mainly used for high power transmission to ensure stable and reliable power connection and is commonly found in server racks and power distribution systems. FIG. 1 to FIG. 11C will discuss the detailed structure of the connector assembly M1.

In the embodiment of FIG. 1, the connector assembly M1 includes a connector 1, a plurality of conductive strip groups 60, a plurality of sockets 200, and a plurality of plugs 100.

For example, the connector assembly M1 has two conductive strip groups 60, which are electrically connected to the connector 1 and extend toward two sides of the connector 1 respectively. On the other hand, the connector assembly M1 also includes two sockets 200 and two plugs 100, in which each socket 200 is electrically connected to a corresponding conductive strip group 60, and each plug 100 is connected or coupled to a corresponding socket 200.

In some embodiments, the two conductive strip groups 60 can be cable assemblies that electrically connect the socket 200 and the connector 1.

In some embodiments, the connector 1 can also be called a busbar clip connector (BBC Connector). That is, the connector 1 has a housing 11, wherein the front side of the housing 11 defines two slots 10. In some embodiments, the slot 10 is a flat long slot having openings on three adjacent sides. The connector 1 further has a plurality of conductive terminal structures 12 inserted into the housing 11. The connector 1 can be used to connect to an external bus system (eg, a bus of a server). For example, the external busbar system may have two external terminals, which are respectively inserted into the slots 10 of the housing 11 and electrically connected to the corresponding conductive terminal structures 12. The two external terminals of the external busbar system can each provide a different electric potential. For example, the two different electric potentials are a positive voltage and a ground voltage respectively.

On the other hand, each conductive strip group 60 has a first conductive strip 60A and a second conductive strip 60B. The first conductive strip 60A and the second conductive strip 60B respectively have a fixed portion (or may be called a first connecting portion), a connecting portion (or may be called a second connecting portion), and an extending portion (or may be called a main portion) located between the fixed portion and the connecting portion, wherein the fixed portion of the first conductive strip 60A is electrically connected to one of the conductive terminal structures 12 of the connector 1, and the fixed portion of the second conductive strip 60B is electrically connected to the other conductive terminal structure 12 of the connector 1. That is, the first conductive strip 60A and the second conductive strip 60B can respectively receive different electric potentials provided by the external bus system. For example, the first conductive strip 60A may be a positive busbar, connected to the positive voltage of the power source and delivering current to the load on the circuit board 400, while the second conductive strip 60B may be a negative busbar, connected to the ground voltage of the power source and delivering return current back to the power source.

The first conductive strip 60A and the second conductive strip 60B of each conductive strip group 60 are electrically insulated from each other. In some embodiments, the first conductive strip 60A and the second conductive strip 60B may be covered with an insulating film or an insulating member to prevent the first conductive strip 60A and the second conductive strip 60B from being short-circuited due to contact. In other embodiments, the first conductive strip 60A and the second conductive strip 60B may be made of a rigid material, such as brass, and there may be a sufficient gap between the first conductive strip 60A and the second conductive strip 60B to prevent the first conductive strip 60A and the second conductive strip 60B from contacting each other.

The extension portions of the first conductive strip 60A and the second conductive strip 60B in each conductive strip group 60 extend from the connector 1 and are arranged side by side. Then, the connecting portions are connected to different socket terminals in the socket 200. The parallel arrangement of the extending portions can minimize the arrangement space of the first conductive strip 60A and the adjacent second conductive strip 60B outside the connector 1 and the socket 200.

In addition, in the embodiment of FIG. 1, the plug 100 is mounted on the circuit board 400 and docked with the corresponding socket 200. In some embodiments, the circuit board 400 is a mainboard of a server. The different electric potentials provided by the two external terminals of the external bus system can be transmitted to the corresponding circuit board 400 through the connector 1 and via the corresponding conductive strip group 60, the socket 200, and the plug 100. It should be understood that although FIG. 1 shows two circuit boards 400, in other embodiments, these circuit boards 400 may be different parts of a single circuit board. In some embodiments, the circuit board 400 may also be a conductive strip or a printed circuit board (PCB), which is disposed on the connecting plug 100 and provides current transmission.

In the embodiment of FIG. 1, the plug 100 is docked or coupled with a corresponding socket 200, and a connection panel 300 is provided between the plug 100 and the socket 200. The socket 200 may be installed on the connection panel 300, and the plug 100 is inserted into the corresponding socket 200 through a hole on the connection panel 300. In some embodiments, the connection panel 300 may be a part of the housing of the server. It should be understood that although FIG. 1 shows two connection panels 300, in other embodiments, these connection panels 300 may be different parts of one connection panel.

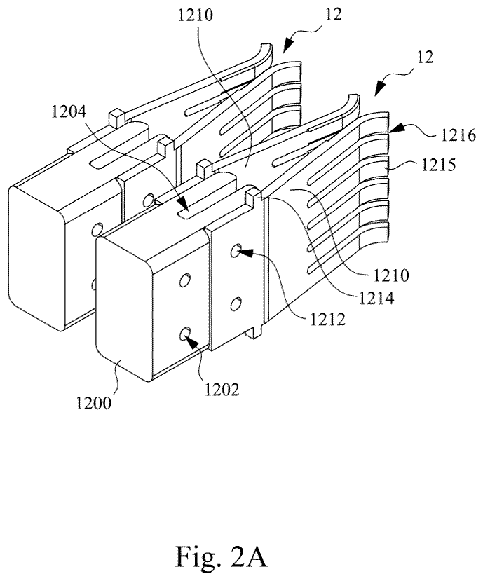

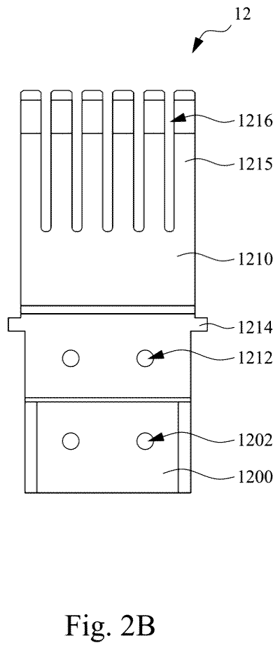

FIG. 2A is a perspective view of a conductive terminal structure, in accordance with some embodiments of the present disclosure and FIG. 2B is a side view of a conductive terminal structure, in accordance with some embodiments of the present disclosure, which will discuss the detailed structure of the conductive terminal structure 12 in the housing 11 of the connector 1 of FIG. 1.

Each of the conductive terminal structures 12 has a conductive block 1200 and a pair of spring clips 1210 connected to the conductive block 1200. The spring clips 1210 are arranged opposite to each other and gradually approach each other in a direction away from the conductive block 1200, and together form a socket with press-fit elasticity. Please refer to FIG. 1. When the conductive terminal structure 12 is installed in the housing 11 of the connector 1, the socket formed by each pair of spring clips 1210 can correspond to the slot 10 of the housing 11 of the connector 1.

When an external terminal passes through the slot 10 of the housing 11 and is inserted into the socket formed by the spring clip 1210, the pressing force generated by the spring clip 1210 can make the spring clip 1210 contact and press the external terminal to maintain the positive force of the spring clip 1210 on the external terminal within a predetermined range, for example: 100 to 200 gf (gram-force), so that the contact impedance between the external terminal and the spring clip 1210 is appropriately reduced, and the surface will not be excessively worn due to friction caused by excessive positive force.

In some embodiments, the conductive block 1200 may have a plurality of holes 1202, and the spring clip 1210 may have a plurality of holes 1212, wherein the holes 1212 of the spring clip 1210 may correspond to some of the holes 1202 of the conductive block 1200, thereby allowing a fixing element (such as a rivet or a screw) to pass through the holes 1212 of the spring clip 1210 and the holes 1202 of the conductive block 1200 to fix the spring clip 1210 and the conductive block 1200 together. In some embodiments, the front end of the conductive block 1200 for fixing the spring clip 1210 has a mounting groove, so that the surface of the spring clip 1210 after fixing is flush with the rear end surface of the conductive block 1200. In some embodiments, another portion of the holes 1202 of the conductive block 1200 do not correspond to the holes 1212 of the spring clip 1210, and these holes 1202 can be used to fix other components to the conductive block 1200.

In some embodiments, the conductive block 1200 further has a groove 1204, wherein the groove 1204 can be used to couple with the protruding member 1110 of the housing 11 of the connector 1. In some embodiments, two opposite ends of the rear end of each spring clip 1210 respectively have a protruding structure 1214, wherein the protruding structure 1214 can be used to be embedded in a corresponding groove on the inner surface of the housing 11 of the connector 1.

In some embodiments, the front edge of the spring clip 1210 has a plurality of contact terminals 1215, wherein the contact terminals 1215 are arranged in a vertical direction and are separated from each other by gaps 1216. In addition, please refer to FIG. 2B, the width of each contact terminal 1215 is greater than the width of each gap 1216, and the preferred ratio is 2:1 or above to ensure that the conductive terminal structure 12 and the external terminal have sufficient contact area to support a larger current.

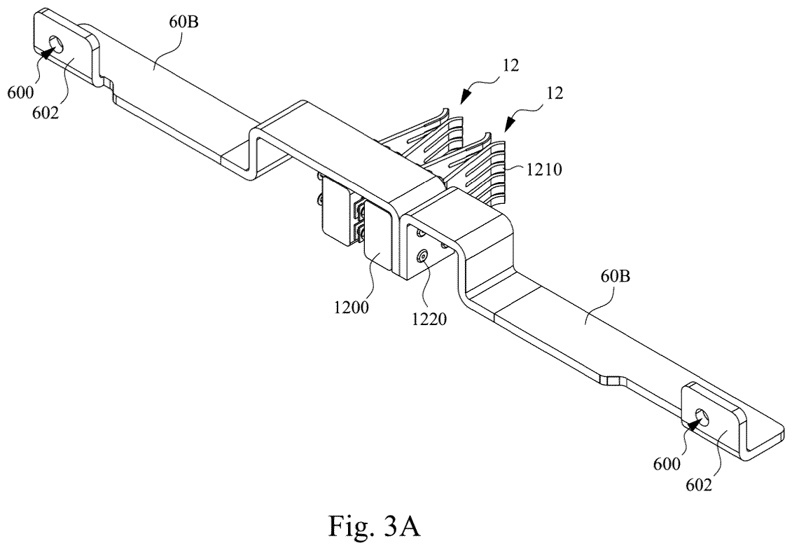

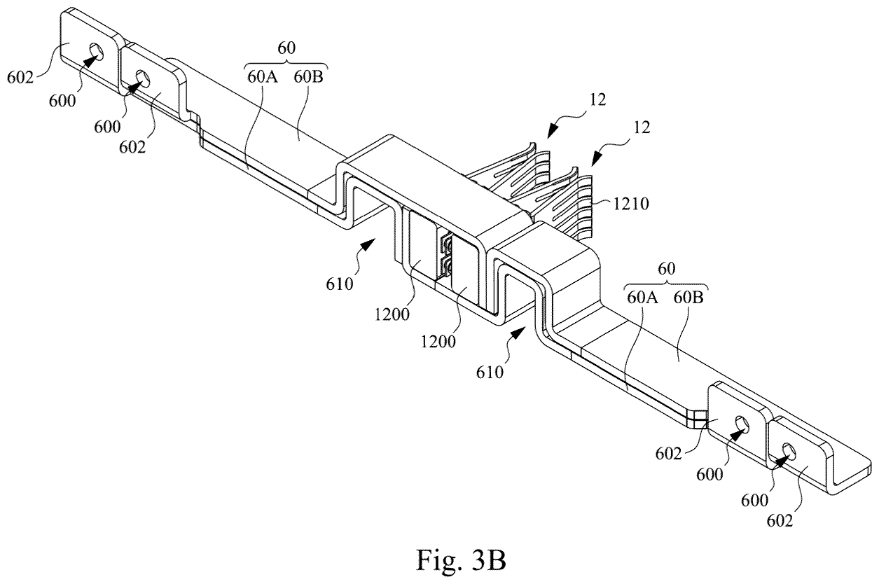

FIG. 3A and FIG. 3B are perspective views of a conductive terminal structure and a conductive strip group of the embodiment, which will discuss the connection relationship between the conductive terminal structure 12 and the conductive strip group 60 of the connector 1 of FIG. 1. For ease of viewing, FIG. 3A only shows the second conductive strip 60B in the conductive strip group 60.

Please refer to FIG. 3A. In some embodiments, two second conductive strips 60B may be fixed to one of the conductive terminal structures 12. In some embodiments, one end (fixed portion) of the two second conductive strips 60B also has a hole. Then, a fixing element 1220 can pass through the holes of the two second conductive strips 60B and the holes of the conductive block 1200 to fix the two second conductive strips 60B and their corresponding conductive terminal structures 12 together. In some embodiments, part of the fixing portion is on the outer surface of the spring clip 1210, that is, part of the hole of the fixing portion is aligned with the hole 1212 of the spring clip 1210 so that the spring clip 1210 is clamped between the second conductive strip 60B and the conductive block 1200. The two second conductive strips 60B and the conductive terminal structure 12 are electrically connected to each other by contact. In some embodiments, the fixing element 1220 may be a rivet or a screw, or other suitable fixing elements. In some embodiments, the fixed portions of the two second conductive strips 60B overlap and are fixed on the surface of the outer side (the side away from the other conductive terminal structure 12) of the conductive terminal structure 12. The extension portions of the two second conductive strips 60B extend from the same side (e.g., upper side) of the conductive block 1200 to the left and right sides respectively. The fixing portion and the extending portion have an angle in between, and are preferably perpendicular to each other. In some embodiments, the extension portions of the two second conductive strips 60B may extend from different sides (e.g., the upper side and the lower side) of the conductive block 1200 to the left and right sides respectively.

Next, please refer to FIG. 3B. After the two second conductive strips 60B are fixed to one of the conductive terminal structures 12, the two first conductive strips 60A can be fixed to the other conductive terminal structure 12. In some embodiments, the fixed portions of the two first conductive strips 60A overlap and are fixed to the outer side of another conductive terminal structure 12. The connection relationship between the first conductive strip 60A and the corresponding conductive terminal structure 12 is substantially the same as the connection relationship between the second conductive strip 60B and the corresponding conductive terminal structure 12, and thus will not be described in detail. In other embodiments, the two first conductive strips 60A may be fixed to one conductive terminal structure 12 first, and then the two second conductive strips 60B may be fixed to another conductive terminal structure 12. The extension parts of the two second conductive strips 60B fixed on the conductive block 1200 extend from the same side to the left and right sides respectively, and the extension parts of the two first conductive strips 60A fixed on the other conductive block 1200 extend from different sides to the left and right sides respectively. Such a design enables an extension portion of a conductive strip to pass adjacent to the upper side and the lower side of each conductive block 1200, thereby forming a vertically symmetrical layout.

In some embodiments, the first conductive strip 60A and the second conductive strip 60B each have a connecting portion 602 at one end away from the conductive terminal structure 12, and each connecting portion 602 has a hole 600. In some embodiments, the connecting portion 602 is a plate-like structure and has an angle with the extending portion. Preferably, the connecting portion 602 and the extending portion are perpendicular to each other. In some embodiments, the connection portions 602 of the first conductive strip 60A and the second conductive strip 60B are aligned with each other. On the other hand, each of the conductive strip groups 60 can be bent to form a receiving space 610 on one side of the conductive terminal structure 12. In some embodiments, the accommodating space 610 has a “U-shaped” cross-sectional profile. The accommodating space 610 helps to fix the housing 11 of the connector 1 to external components.

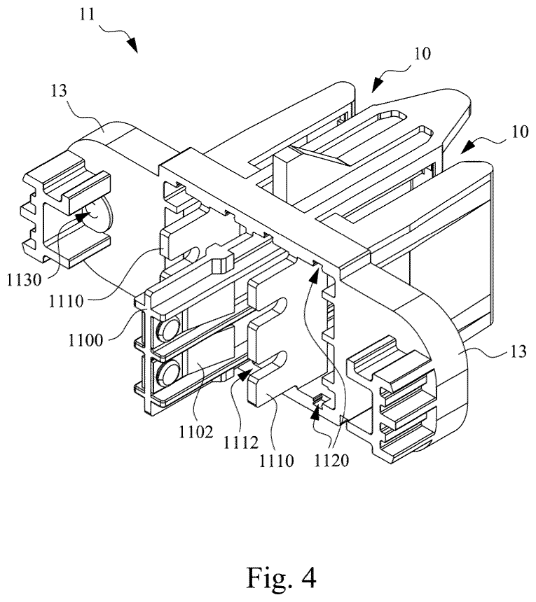

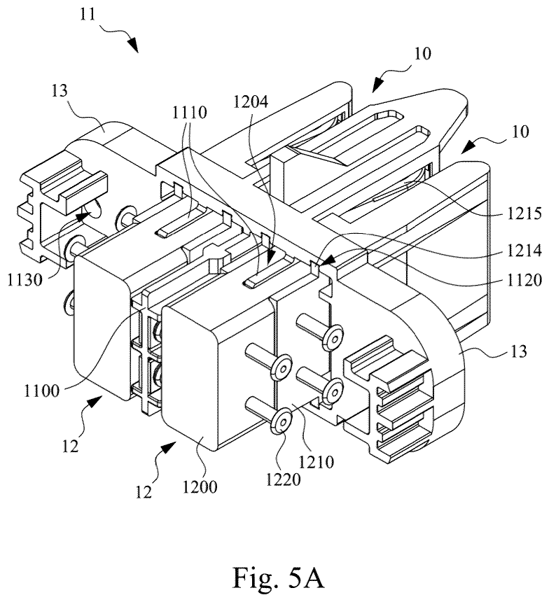

FIG. 4 is a perspective view of a housing of a connector, in accordance of some embodiments of the present disclosure, which will discuss the detailed structure of the housing 11 of the connector 1 of FIG. 1.

The housing 11 has wings 13 extending toward opposite sides of the housing 11. In some embodiments, each wing portion 13 has at least one hole 1130. The housing 11 can be fixed to an external housing, such as a housing of a server, by means of the wing 13. For example, the surface of the wing 13 facing the slot 10 can be pressed against an external housing, and the hole 1130 of the wing 13 can be aligned with the hole on the external housing. Next, a fixing element, such as a screw or a rivet, is passed through the hole 1130 of the wing 13 and the hole on the outer housing to lock the wing 13 of the housing 11 on the outer housing. In addition, please refer to FIG. 1 and FIG. 3B, the hole 1130 of the wing 13 will correspond to the accommodation space 610 formed by the conductive strip group 60. In this way, the wing 13 of the housing 11 can be locked on the external housing by using a fixing element through the accommodating space 610 without being blocked.

The housing 11 also has a protruding structure 1100 and two protruding members 1110, which are respectively located on both sides of the protruding structure 1100. In some embodiments, the protruding structure 1100 extends a greater distance than the protruding member 1110. In some embodiments, the protruding structure 1100 further has a plurality of spring pieces 1102, wherein the spring pieces 1102 are respectively disposed on two opposite surfaces of the protruding structure 1100. In some embodiments, two spring pieces 1102 are respectively disposed on one side of the protruding structure 1100. In some embodiments, the spring piece 1102 may be a metal sheet, and the rear end may be fixed to the protruding structure 1100 through a fixing element such as a rivet or a screw, while the front end is a free end and deviates outward in a direction away from the protruding structure 1100. On the other hand, the protruding member 1110 has a groove 1112. In some embodiments, each protruding member 1110 has a plurality of grooves 1112. In addition, a plurality of grooves 1120 are also disposed in the upper inner surface and the lower inner surface of the housing 11.

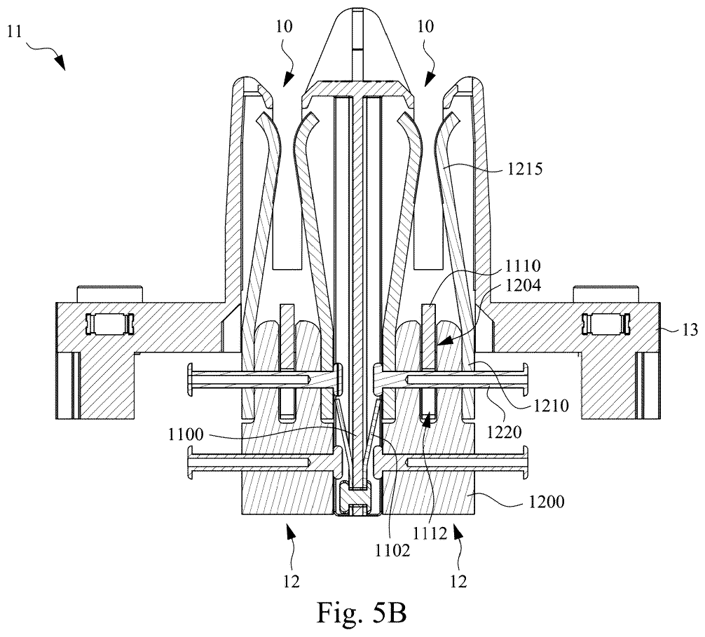

FIG. 5A is a perspective view of a conductive terminal structure and a housing, in accordance with some embodiments of the present disclosure, and FIG. 5B is a cross-sectional view of a conductive terminal structure and a housing, in accordance with some embodiments of the present disclosure, which will discuss the connection relationship between the conductive terminal structure 12 and the housing 11 of the connector 1 of FIG. 1.

In some embodiments, as discussed in FIG. 3A and FIG. 3B, the conductive strip group 60 is first mounted on the conductive terminal structure 12, and then the conductive terminal structure 12 is inserted into the housing 11. However, for the sake of ease of viewing, the conductive strip group 60 is not shown in FIG. 5A or FIG. 5B.

First, two conductive terminal structures 12 are respectively inserted into the housing 11 along opposite sides of the protruding structure 1100 of the housing 11. As a result, the protruding structure 1100 will be located between the two conductive terminal structures 12, so that the two conductive terminal structures 12 are electrically isolated from each other. The contact terminal 1215 of the spring clip 1210 of the conductive terminal structure 12 will extend to the position of the slot 10 of the housing 11.

In addition, the protruding structure 1214 of the spring clip 1210 of the conductive terminal structure 12 will be embedded in the groove 1120 of the housing 11. Such a design can limit the movement of the conductive terminal structure 12 on a plane perpendicular to the slot 10, so as to fix the conductive terminal structure 12 on the housing 11.

On the other hand, the protruding member 1110 of the housing 11 will be embedded in the groove 1204 of the conductive block 1200 of the conductive terminal structure 12. In addition, in the cross-sectional view of FIG. 5B, a portion of the fixing element 1220 passing through the conductive terminal structure 12 is exposed to the groove 1204 of the conductive block 1200, and the portion of the fixing element 1220 is embedded in the groove 1112 of the protruding member 1110. Likewise, such a design can also limit the movement of the conductive terminal structure 12 in a plane perpendicular to the slot 10 and forward (toward the slot 10), so as to fix the conductive terminal structure 12 on the housing 11.

Please refer to FIG. 5B. When the conductive terminal structure 12 is inserted into the interior of the housing 11, the fixing element 1220 on the conductive terminal structure 12 will squeeze the front end (free end) of the spring piece 1102 located on the protruding structure 1100 of the housing 11 inward until the fixing element 1220 passes through the spring piece 1102. Then, the spring piece 1102 rebounds and rests against the fixing element 1220 and the spring clip 1210 of the conductive terminal structure 12. Such a design can ensure that the conductive terminal structure 12 will not fall off after being inserted into the housing 11.

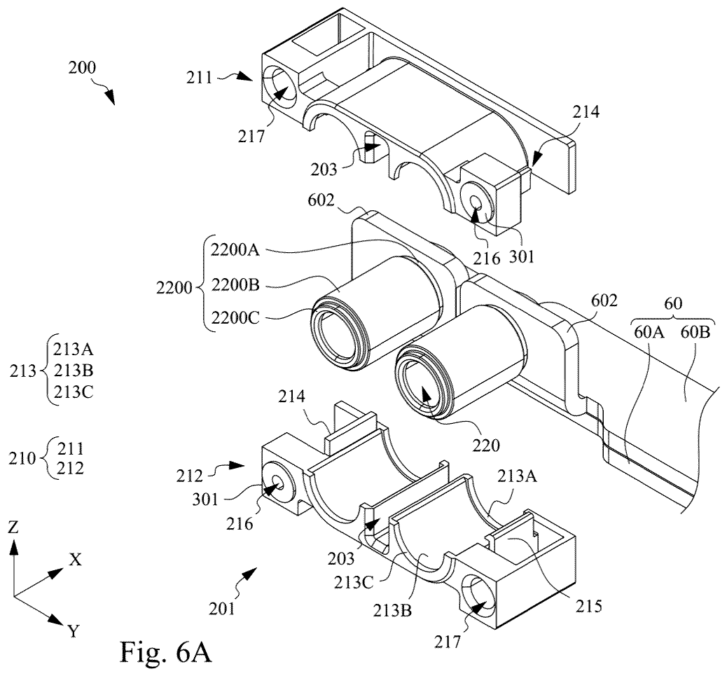

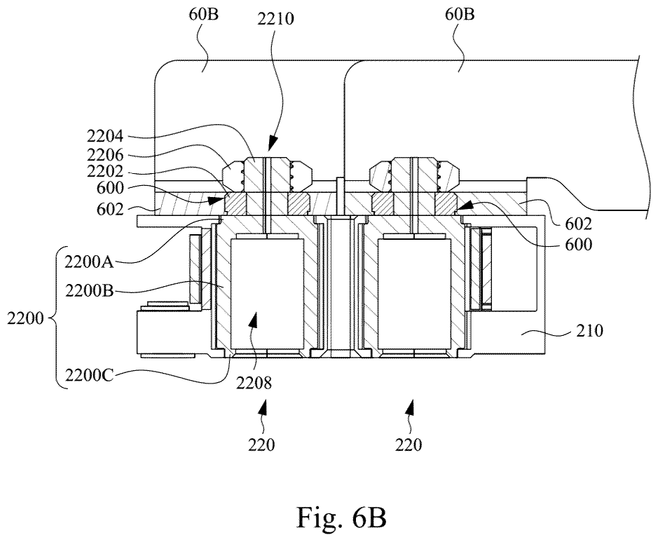

FIG. 6A is a perspective view of a conductive strip group and a socket, in accordance with some embodiments of the present disclosure, and FIG. 6B is a cross-sectional view thereof, which will discuss the connection relationship between the conductive strip group 60 and the socket 200 of FIG. 1.

In some embodiments, the socket 200 has a socket housing 210 and a plurality of socket connectors 220 (or may be referred to as socket terminals). In some embodiments, each socket 200 has two socket connectors 220. First, two socket connectors 220 may be installed on the first conductive strip 60A and the second conductive strip 60B of the conductive strip group 60, respectively. In some embodiments, the socket connector 220 may include copper, copper alloy, or similar conductive materials.

Please refer to FIG. 6B first. Each socket connector 220 has a main body portion 2200, an embedded portion 2202 connected to the main body portion 2200, and a locking portion 2204 connected to the embedded portion 2202. In some embodiments, the main body 2200, the embedded portion 2202, and the locking portion 2204 are substantially cylindrical in appearance, the diameter of the main body 2200 is larger than the diameter of the embedded portion 2202, and the diameter of the embedded portion 2202 is larger than the diameter of the locking portion 2204. During installation, the embedding portion 2202 of the socket connector 220 may be inserted into the hole 600 of the connecting portion 602 of the first conductive strip 60A (or the second conductive strip 60B). In some embodiments, the diameter of the embedded portion 2202 of the socket connector 220 is slightly larger than the diameter of the hole 600, which can ensure that the embedded portion 2202 can be firmly inserted into the hole 600 of the connecting portion 602 of the first conductive strip 60A (or the second conductive strip 60B). Additionally, the surface of the embedding portion 2202 may have teeth marks, which will help snap the embedding portion 2202 into the hole 600. In some embodiments, the main body portion 2200 and the embedded portion 2202 may be a cuboid or other polyhedral structures.

Thus, the main body portion 2200 having a larger diameter will abut against one side of the first conductive strip 60A (or the second conductive strip 60B), and the locking portion 2204 will protrude from the other side of the first conductive strip 60A (or the second conductive strip 60B). In some embodiments, the surface of the locking portion 2204 has threads. Therefore, the fixing element 2206, such as a nut, can be screwed into the locking portion 2204, thereby locking the socket connector 220 on the corresponding first conductive strip 60A or second conductive strip 60B and establishing an electrical connection therewith.

In addition, the main body 2200 of the socket connector 220 has a first portion 2200A, a second portion 2200B and a third portion 2200C, wherein the second portion 2200B is located between the first portion 2200A and the third portion 2200C. In some embodiments, the width (diameter) of the second portion 2200B is greater than the width (diameter) of the first portion 2200A and the third portion 2200C.

On the other hand, the socket connector 220 also has a slot 2208 located in the main body 2200, wherein the slot 2208 is used to connect to the conductive terminal of the plug. A conductive annular elastic element (e.g., a crown spring) can be installed in the slot 2208 to strengthen the electrical connection between the socket connector 220 and the conductive terminal. In addition, the socket connector 220 further has an air hole 2210 that passes through the main body portion 2200, the embedding portion 2202, the locking portion 2204, and is connected to the slot 2208. Thus, when a conductive terminal is inserted into the slot 2208 of the socket connector 220, the air inside the slot 2208 can be exhausted through the air hole 2210, so as to facilitate the insertion of the external terminal into the socket connector 220. In addition, the air hole 2210 can also be used as a flow channel for the plating solution when the socket connector 220 is electroplated.

Please refer back to FIG. 6A, the socket housing 210 includes an upper housing 211 and a lower housing 212. In some embodiments, the upper housing 211 and the lower housing 212 are assembled to form an alignment groove corresponding to the shape of the socket connector 220, so as to position the socket connector 220 in the socket housing 210. That is, each of the upper housing 211 and the lower housing 212 has two alignment slots 213, wherein the alignment slots 213 have a substantially semicircular profile. When the upper housing 211 is combined with the lower housing 212, the alignment slot 213 of the upper housing 211 and the corresponding alignment slot 213 of the lower housing 212 will merge to form a circular receiving groove, and the socket connector 220 with a cylindrical structure can be positioned in the circular receiving groove. The receiving groove is formed corresponding to the contour of the main body 2200 of the socket connector 220, and in some embodiments, it can be a rectangular groove or a multi-faceted groove.

In more detail, the alignment slot 213 may have a first portion 213A, a second portion 213B, and a third portion 213C, wherein the second portion 213B is located between the first portion 213A and the third portion 213C. In some embodiments, the diameter of the second portion 213B is greater than the diameters of the first portion 213A and the third portion 213C. Among them, the diameter of the first part 213A of the alignment slot 213 roughly matches the diameter of the first part 2200A of the main part 2200 of the socket connector 220, the diameter of the second part 213B of the alignment slot 213 roughly matches the diameter of the second part 2200B of the main part 2200 of the socket connector 220, and the diameter of the third part 213C of the alignment slot 213 roughly matches the diameter of the third part 2200C of the main part 2200 of the socket connector 220. Such a design can ensure that the socket connector 220 will not slide or fall off in the socket housing 210 after the upper housing 211 and the lower housing 212 are combined.

On the other hand, the upper housing 211 and the lower housing 212 each have a positioning groove 203, wherein the positioning groove 203 has a narrow and long profile. When the upper housing 211 is combined with the lower housing 212, the positioning groove 203 of the upper housing 211 and the corresponding positioning groove 203 of the lower housing 212 will be combined to form a long and narrow groove body.

In some embodiments, the upper housing 211 and the lower housing 212 can be fixed together through a buckle structure 215 located on each other's side surfaces. Specifically, one end of the upper housing 211 has a buckle structure 215, and the other end has a groove 214. Similarly, the lower housing 212 has a buckle structure 215 at one end and a groove 214 at the other end. When the upper housing 211 and the lower housing 212 are assembled, the buckle structure 215 of the upper housing 211 is engaged with the groove 214 of the lower housing 212, and the buckle structure 215 of the lower housing 212 is engaged with the groove 214 of the upper housing 211, thereby firmly combining the upper housing 211 and the lower housing 212.

In some embodiments, the socket housing 210 has a plurality of locking holes 216 in the direction of the mating surface 201 of the socket 200. In some embodiments, the socket housing 210 further has a plurality of positioning holes 217. Specifically, the upper housing 211 and the lower housing 212 have a locking hole 216 and a positioning hole 217 respectively. In some embodiments, the locking hole 216 and the positioning hole 217 of the socket housing 210 may be located on diagonal lines of the mating surface 201, respectively. In some embodiments, a limiting element 301 is installed in the locking hole 216.

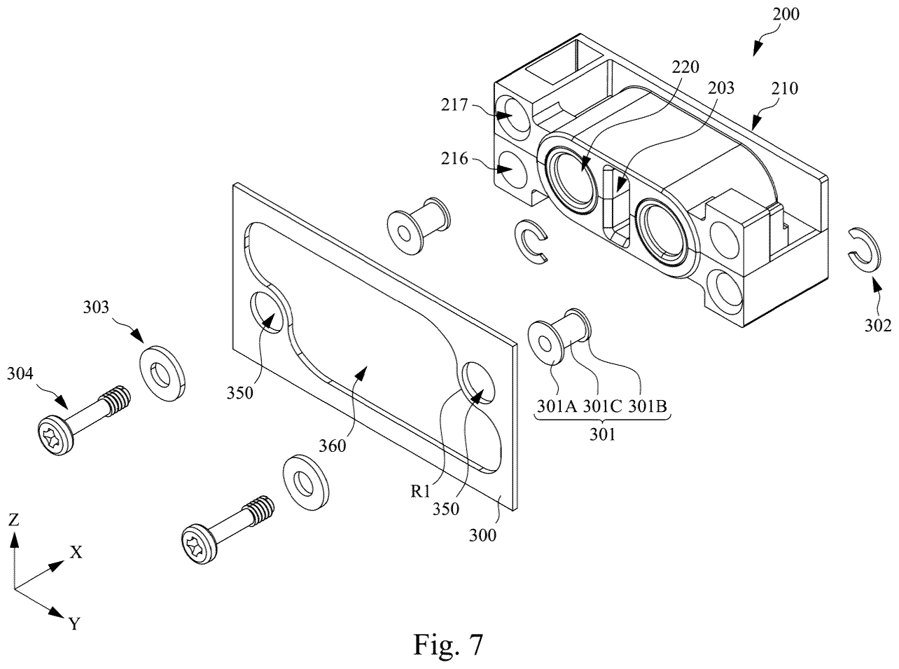

FIG. 7 is a perspective view of a socket and a connection panel, in accordance with some embodiments of the present disclosure, which will discuss the connection relationship between the socket 200 and the connection panel 300 of FIG. 1.

In some embodiments, the socket housing 210 of the socket 200 can be locked onto the connection panel 300, wherein the connection panel 300 is locked together with the socket housing 210 via locking holes 216 located at the diagonal of the socket housing 210. In some embodiments, the connection panel 300 has three openings, including two openings 350 and an opening 360 located between the two openings 350. The positions of the two openings 350 are substantially aligned with and expose the locking holes 216 of the socket housing 210 of the socket 200. In some embodiments, the two openings 350 may be connected to the opening 360 (for example, a portion of the boundary between the opening 350 and the opening 360 in the figure may not exist), and in this case, the two openings 350 are equivalent to two extension areas of the opening 360.

On the other hand, the opening 360 is configured to expose at least the mating area of the socket connector 220 of the socket 200 (e.g., the slot 2208). In some embodiments, the opening 360 also exposes the positioning hole 217 and the positioning groove 203. In some embodiments, the opening 350 and the opening 360 are not connected to each other. In some embodiments, the area of the opening 360 is larger than the area of the opening 350. In some embodiments, the opening 360 has a step-like profile.

From another perspective, the profile of the opening 360 has two recessed portions R1, wherein the opening 350 is respectively adjacent to the recessed portions R1 of the opening 360.

The locking hole 216 of the socket housing 210 and the opening 350 of the connection panel 300 have sizes that match or are similar to each other. In some embodiments, the opening 350 of the connection panel 300 is larger than the locking hole 216. The locking hole 216 is a through hole, and a first opening and a second opening are respectively formed on two surfaces of the socket housing 210. The locking mechanism includes inserting and disposing the limiting element 301 in the locking hole 216 of the socket housing 210. In some embodiments, the limiting element 301 includes a first end 301A, a second end 301B, and a main body portion 301C located between the first end 301A and the second end 301B. In some embodiments, the first end 301A, the second end 301B and the main body 301C all have a circular cross-sectional profile, wherein the outer frame (diameter) of the first end 301A and the second end 301B is larger than the outer frame (diameter) of the main body 301C, and the outer frame (diameter) of the first end 301A is larger than the outer frame (diameter) of the second end 301B. On the other hand, the outer frames (diameters) of the second end 301B and the main body 301C are both smaller than the outer frame (diameter) of the locking hole 216, while the outer frame (diameter) of the first end 301A is larger than the outer frame (diameter) of the locking hole 216. Therefore, when placing the limiting element 301 into the locking hole 216, first insert the second end 301B and the main body 301C of the limiting element 301 with a smaller diameter into the locking hole 216 from the first opening. As the limiting element 301 moves into the locking hole 216, the first end 301A with a larger diameter will no longer be able to enter the locking hole 216, so that the first end 301A of the limiting element 301 will abut against the outer wall surface of the socket housing 210. At this time, the second end 301B passes through the locking hole 216 from the second opening and is exposed to the outside.

The limiting element 301 has a through hole extending there through. In some embodiments, the limiting element 301 may be made of plastic, and the through hole of the limiting element 301 may have a smooth inner surface. In other embodiments, the limiting element 301 may be made of metal, and the through hole of the limiting element 301 may have a threaded inner surface.

In some embodiments, setting the limiting element 301 in the locking hole 216 of the socket housing 210 also includes using a C-shaped ring 302 (or can be called an auxiliary piece) to fix the limiting element 301. In some embodiments, the C-shaped ring 302 is substantially a circular ring structure with an opening. The opening of the C-shaped ring 302 is detachably configured to be inserted into the main body portion 301C of the limiting element 301. That is to say, the inner diameter of the C-shaped ring 302 is substantially the same as or slightly larger than the diameter of the main body 301C of the limiting element 301, so that the C-shaped ring 302 can be stably set on the main body 301C of the limiting element 301. On the other hand, the outer diameter of the C-shaped ring 302 is larger than the diameter of the locking hole 216 of the socket housing 210 (i.e., the diameter of the opening of the locking hole 216 adjacent to the C-shaped ring 302), which will prevent the C-shaped ring 302 from sliding into the locking hole 216 and abutting against the surface of the socket housing 210, and help to further fix the limiting element 301 on the socket housing 210.

Next, a screw 304 is inserted from the other side of the connection panel 300 through the opening 350 and into the through hole of the limiting element 301. In some embodiments, fixing the connection panel 300 to the socket housing 210 of the socket 200 further includes using a washer 303, wherein the washer 303 has a ring structure, and the screw 304 can pass through the washer 303 and then into the opening 350 and the through hole of the limiting element 301. In some embodiments, the outer diameter of the washer 303 is greater than the diameter of the opening 350 of the connection panel 300, so that the washer 303 can completely abut against a surface of the connection panel 300, thereby fixing the connection panel 300 on the socket housing 210 of the socket 200.

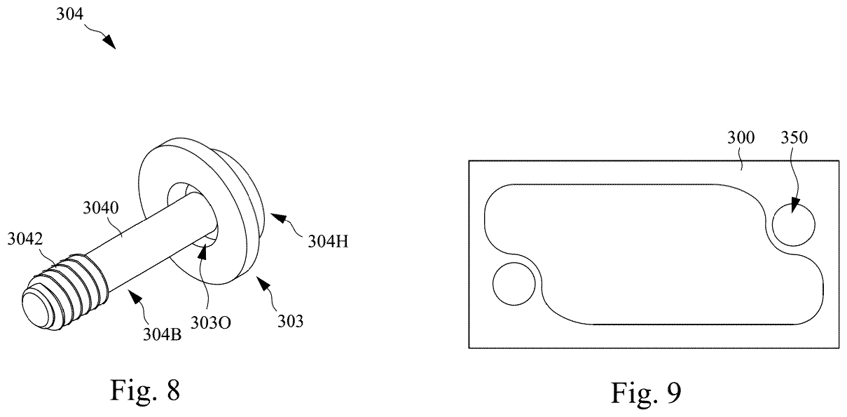

FIG. 8 is a perspective view of a washer and a screw, in accordance with some embodiments of the present disclosure, which will discuss the detailed structure of the screw 304 in FIG. 7. In some embodiments, the screw 304 has a screw head 304H and a screw pin 304B. The screw pin 304B has a top 3040 and a bottom 3042, wherein the top 3040 is located between the bottom 3042 and the screw head 304H. In some embodiments, the top 3040 of the screw pin 304B has a smooth surface, while the bottom 3042 of the screw pin 304B has a threaded surface. In some embodiments, the washer 303 has a washer opening 303O. In some embodiments, the diameter of the washer opening 303O is larger than the diameter of the screw pin 304B and smaller than the diameter of the screw head 304H. In some embodiments, the outer diameter of the washer 303 is larger than the diameter of the screw head 304H. In some embodiments, the outer diameter of the washer 303 is about 6 mm or more, and the diameter of the screw pin 304B is about 5 mm or less.

FIG. 9 is a perspective view of a connection panel, in accordance with some embodiments of the present disclosure. In some embodiments, the size of the opening 350 of the connection panel 300 can be adjusted as needed. In some embodiments, the diameter of the opening 350 of the connection panel 300 is larger than the diameter of the screw pin 304B. In some embodiments, if the diameter of the screw pin 304B is about 2.5 mm, the diameter of the opening 350 may be about 6.8 mm.

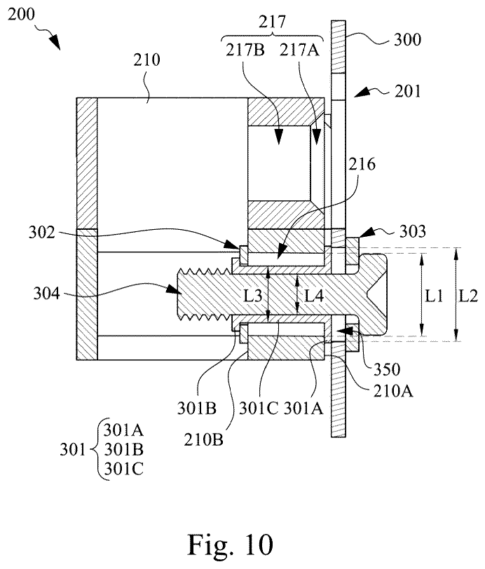

FIG. 10 is a cross-sectional view of a connection panel and a socket, in accordance with some embodiments of the present disclosure. The following will first discuss the mechanism for locking the socket housing 210 of the socket 200 onto the connection panel 300. As mentioned above, the limiting element 301 is inserted into the locking hole 216 on the socket housing 210 from the outer surface (or first surface) 210A of the socket housing 210. Since the length of the main portion 301C of the limiting element 301 is slightly longer than the length of the locking hole 216, the main portion 301C of the limiting element 301 has a portion protruding from the inner surface (or second surface) 210B of the socket housing 210, so that the second end 301B is exposed. The C-shaped ring 302 inserted into the main body portion 301C abuts against (is located between) the inner surface 210B of the socket housing 210 and the second end 301B of the limiting element 301. It can be seen that by providing the C-shaped ring 302, the limiting element 301 can be fixed in the locking hole 216 of the socket housing 210 without falling off and has the function of buffering friction. However, since the main body portion 301C of the limiting element 301 has a relatively small diameter, there is a floating space between the main body portion 301C of the limiting element 301 and the locking hole 216. That is to say, although the limiting element 301 is fixed on the socket housing 210, the limiting element 301 can still slide in the locking hole 216, and this floating space provides more flexibility for docking the socket 200 with the plug 100.

Next, the socket 200 can be pressed against the connection panel 300. In more detail, the opening 350 of the connection panel 300 is substantially aligned with the through hole of the limiting element 301, and one side of the connection panel 300 can abut against the first end 301A of the limiting element 301. Next, the washer 303 is pressed against the other side of the connection panel 300, and the screw 304 is inserted through the opening of the washer 303 and the opening 350 of the connection panel 300 and coupled to the limiting element 301.

Referring to FIG. 10, the locking hole 216 of the socket housing 210 has a diameter L1, and the opening 350 of the connection panel 300 has a diameter L2. On the other hand, the main body portion 301C of the limiting element 301 has a diameter L3, wherein the diameter L3 is smaller than the diameter L1 of the locking hole 216. Furthermore, the screw 304 has a diameter L4, wherein the diameter L4 is smaller than the diameter L2 of the opening 350 of the connection panel 300.

It can be seen from this that the main portion 301C of the limiting element 301 can slide in the locking hole 216, and the maximum floating distance is (diameter L1-diameter L3). Similarly, the screw 304 can slide in the opening 350 of the connection panel 300, and the maximum floating distance is (diameter L2-diameter L4). It can be seen that, assuming that the position of the connection panel 300 is fixed, the socket housing 210 can slide relative to the connection panel 300, and the maximum floating dimension is (diameter L1-diameter L3)+(diameter L2-diameter L4). In some embodiments, the difference between the outer diameter of the washer 303 and the diameter L2 of the opening 350 is greater than or equal to the difference between the diameter L2 and the diameter L4. In some embodiments, the difference between the outer diameter of the C-shaped ring 302 and the diameter L1 of the locking hole 216 is greater than or equal to the difference between the diameter L1 and the diameter L3. This arrangement ensures that during the sliding process, the outer edge of the washer 303 will not be partially within the projection of the opening 350, and the outer edge of the C-shaped ring 302 will not be partially within the projection of the locking hole 216.

In some embodiments, the locking hole 216 can be a non-circular (e.g., quadrilateral) through hole, and the profile of the main portion 301C of the limiting element 301 located in the locking hole 216 is roughly consistent with the surface profile of the locking hole 216 but smaller, so that there is floating space between them. Similarly, the profile of the bottom 3042 of the screw 304 and the profile of the opening 350 may be non-circular and roughly the same but smaller, so that there is a floating space between them.

Therefore, the floating range between the socket housing 210 and the connection panel 300 can be adjusted according to usage requirements by designing the main part 301C of the limiting element 301, the locking hole 216, the opening 350 on the connection panel 300 or the size of the screw 304 to meet different usage requirements. In some embodiments, a nut may be used to lock onto the threads of the bottom 3042. By adjusting the locking force of the nut, the friction between the socket housing 210 and the connection panel 300 can be adjusted, so that after the socket housing 210 and the connection panel 300 move relative to each other, the relative position of the socket housing 210 and the connection panel 300 is fixed due to the friction.

In other words, the limiting element 301, the C-shaped ring 302, the washer 303 and the screw 304 form a limiting mechanism, so that the socket housing 210 and the connection panel 300 can be connected together in a relatively movable manner. In more detail, the limiting mechanism clamps at least a portion of the connection panel 300 and the socket housing 210 in between, so that at least a portion of the connection panel 300 and the socket housing 210 are located between two ends of the limiting mechanism. The limiting mechanism can move relative to the socket housing 210 within a first preset range. Alternatively, the limiting mechanism may move relative to the connection panel 300 within a second preset range. Therefore, there is a floating mechanism of the first preset range or the second preset range between the socket housing 210 and the connection panel 300. When both floating mechanisms are set, there is a maximum floating mechanism between the socket housing 210 and the connection panel 300 that is a sum of the first preset range and the second preset range. The socket housing 210, the connection panel 300, the limiting mechanism (the limiting element 301, the C-shaped ring 302, the washer 303, and the screw 304) may be collectively referred to as a connector housing.

On the other hand, referring to the positioning hole 217, the positioning hole 217 has a first portion 217A and a second portion 217B that are connected to each other. In some embodiments, the first portion 217A has a gradually narrowing profile. For example, the first portion 217A has the largest width (or diameter) at a side close to the connection panel 300, and the first portion 217A has the smallest width (or diameter) at a side far from the connection panel 300. In addition, the second portion 217B has a substantially uniform width (or diameter). The contour of the first portion 217A of the positioning hole 217 will help guide a guide post of the plug into the positioning hole 217.

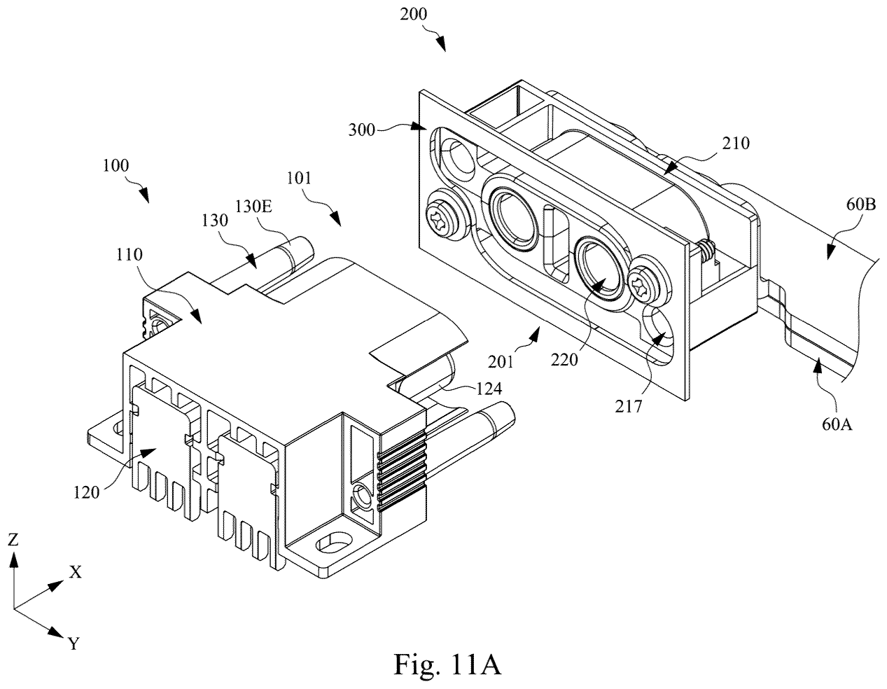

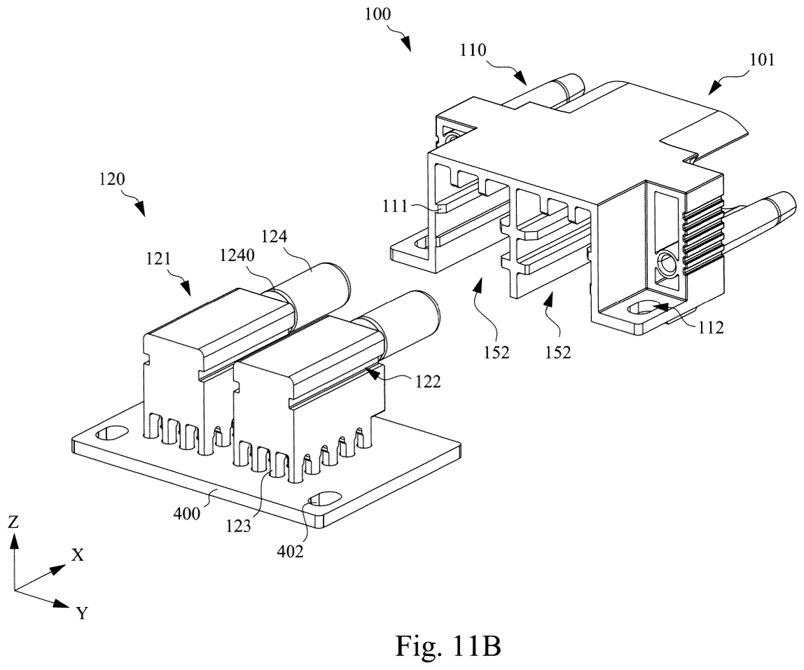

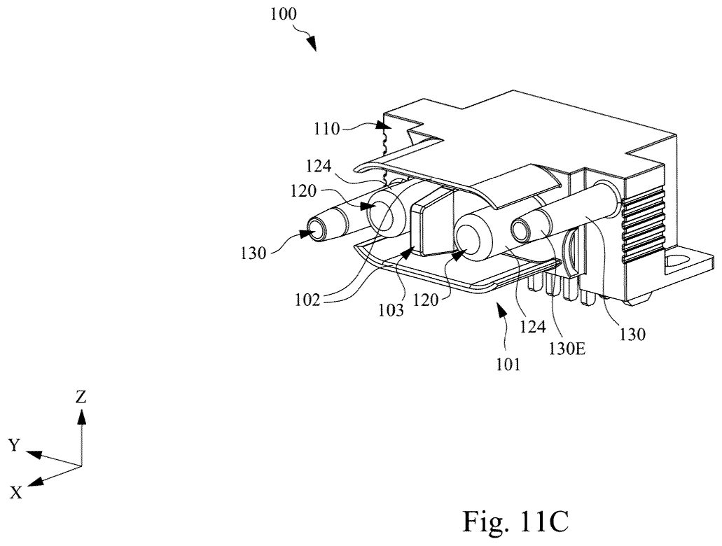

FIG. 11A is a perspective view of a socket and a plug, in accordance with some embodiments of the present disclosure, FIG. 11B is a perspective view of a conductive structure and a circuit board of the plug, in accordance with some embodiments of the present disclosure, and FIG. 11C is a perspective view of a plug, in accordance with some embodiments of the present disclosure, which will discuss the connection relationship between the plug 100, the socket 200 and the circuit board 400 of FIG. 1, as well as the detailed structure of the plug 100.

Refer to FIG. 11A. In some embodiments, the plug 100 includes a plug housing 110 and a plurality of conductive terminals (or plug connectors) 120 located inside the plug housing 110. In some embodiments, the contact terminals 124 of the conductive terminals 120 extend outward from the mating surface 101 of the plug housing 110 (e.g., the direction of mating with the socket 200). In some embodiments, the plug housing 110 includes a guide post 130 extending outwardly from the mating surface 101 of the plug housing 110. In some embodiments, the front end of the guide post 130 is further forward than the front end of the conductive terminal 120.

Furthermore, the connection panel 300 can be fixed to the surface of the socket housing 210 of the socket 200 by screws through the opening 350, and the conductive terminals 120 and the guide posts 130 of the plug 100 will pass through the opening 360 of the connection panel 300 and be connected or coupled to the socket 200.

Specifically, when the plug 100 is inserted into the socket 200, the guide post 130 of the plug 100 is first inserted into the corresponding positioning hole 217 of the socket 200 through the opening 360 of the connection panel 300. Next, the conductive terminals 120 of the plug 100 are respectively inserted into the corresponding socket connectors 220 of the socket 200 through the openings 360 of the connection panel 300, so that the conductive terminals 120 of the plug 100 and the socket connectors 220 of the socket 200 are electrically connected.

Please refer to FIG. 11B. FIG. 11B is a schematic diagram illustrating the plug housing 110 and the conductive terminals 120 of the plug 100 when they are separated. In some embodiments, the plug housing 110 has two accommodating spaces 152 respectively, and the two accommodating spaces 152 are separated by a wall of the plug housing 110, wherein the conductive terminals 120 can be respectively inserted into the plug housing 110 through the corresponding accommodating spaces 152 and are electrically isolated from each other and protrude outward from the mating surface 101 (as shown in FIG. 11C).

In some embodiments, the conductive terminal 120 includes a conductive terminal base 121. In some embodiments, the conductive terminal base 121 is a cuboid or a cube, and has a guide groove 122 along the mating direction on two opposite sides thereof for engaging with the plug housing 110. In some embodiments, the guiding groove 122 may be a recessed area located on a side surface of the conductive terminal base 121.

In some embodiments, the conductive terminal 120 further has a plurality of pins 123 extending downward from the bottom of the conductive terminal base 121 and used to connect the conductive terminal 120 to the circuit board 400. That is, the pins 123 can be inserted into and mounted in holes on the surface of the circuit board 400, and electrically connected to the circuit board 400 through a suitable method (such as welding).

On the other hand, each conductive terminal 120 also has a contact terminal 124 extending forward (in the mating direction) from a side wall of the conductive terminal base 121. The contact terminal 124 has a generally cylindrical profile. In some embodiments, the surface of the contact terminal 124 further has a fixing ring 1240 located in the middle section of the contact terminal 124, wherein the fixing ring 1240 may be a groove surrounding the cylindrical contour of the contact terminal 124. In some embodiments, when the conductive terminal 120 is installed to the plug housing 110, the contact terminal 124 of the conductive terminal 120 will pass through a through hole of the plug housing 110, and the fixing ring 1240 will be embedded in the through hole of the plug housing 110, thereby fixing the contact terminal 124 on the plug housing 110.

In some embodiments, the inner surface of each accommodating space 152 has a plurality of raised guide bars 111 for being embedded in the guide grooves 122 on the conductive terminal base 121. For example, when the conductive terminal 120 is inserted into the accommodating space 152 of the plug housing 110, the guide groove 122 can slide along the corresponding guide bar 111, and further insert the conductive terminal base 121 into the plug housing 110 along a predetermined direction.

In some embodiments, the plug housing 110 further includes a positioning hole 112, which is a hollow structure configured to position and connect the circuit board 400. In some embodiments, similarly, the circuit board 400 further includes a positioning hole 402 which is a hollow structure. For example, the conductive terminal 120 may be mounted on the circuit board 400 first, and then the conductive terminal 120 may be inserted into the receiving space 152 of the plug housing 110. After the conductive terminal 120 is mounted to the plug housing 110, the positioning hole 112 of the plug housing 110 will be aligned with the positioning hole 402 on the circuit board 400. Next, a fixing element (such as a screw) may be passed through the positioning hole 112 and the positioning hole 402 to fix the plug housing 110 on the circuit board 400.

Please refer to FIG. 11C. At the mating surface 101 of the plug 100, the contact terminals 124 of the conductive terminals 120 protrude from one side of the plug housing 110. In some embodiments, the plug 100 further includes a positioning element 102 extending outward from the upper and lower sides of the plug housing 110 and an isolation element (or guide piece) 103 extending from the plug housing 110 and located in the middle of the conductive terminal 120. In some embodiments, the front end of the isolation element 103 is located behind the front end of the guide post 130 but before the front end of the conductive terminal 120.

In some embodiments, the positioning element 102 has a plate-like structure, and the conductive terminal 120 is covered by the upper and lower positioning elements 102. In some embodiments, after the plug 100 is engaged with the socket 200, the positioning element 102 of the plug housing 110 may cover and contact at least a portion of the side surface of the socket housing 210 of the socket 200.

In some embodiments, diagonal corners of the mating surface 101 have non-adjacent guide posts 130. In some embodiments, one end of the guide post 130 facing the mating surface 101 has a tapered end 130E. That is, the tip of the guide post 130 has a gradually narrowing profile.

In some embodiments, the gradually narrowing profile of the guide post 130 allows the plug 100 to have a tolerance space (i.e., the size difference between the tapered end and the non-end) to insert the tapered end 130E of the guide post 130 into the positioning hole 217 through the opening of the connection panel 300 when the plug 100 is not completely aligned with the positioning hole 217 of the socket 200. That is, the guide post 130 can be gradually guided to a position that correctly engages with the positioning hole 217 by inserting the tapered end portion 130E of the guide post 130 (at this time, the socket 200 can be moved relative to the connection panel 300). In some embodiments, a diameter of one end of the tapered end portion 130E facing the mating surface 101 is smaller than a diameter of the other end of the tapered end portion 130E (e.g., the end facing away from the mating surface 101). In some embodiments, a diameter of the other end of the tapered end portion 130E (e.g., the end facing away from the mating surface 101) may be smaller than or equal to a diameter of the guide post 130.

In some embodiments, the guide post 130 and the conductive terminal 120 or the positioning element 102 have substantially the same distance extending outward from the plug housing 110.

Please refer back to FIG. 11A. When the plug 100 is engaged with the socket 200, the conductive terminals 120, the guide posts 130, the positioning elements 102 and the isolation elements 103 of the plug 100 will be inserted into the socket 200 through the openings 360 of the connection panel 300. That is, the conductive terminals 120 of the plug 100 will be inserted into the socket connector 220 of the socket 200 through the openings 360 of the connection panel 300. The guide post 130 of the plug 100 will be inserted into the positioning hole 217 of the socket 200 through the opening 360 of the connection panel 300. The positioning element 102 of the plug 100 will pass through the opening 360 of the connection panel 300 and cover the socket housing 210 of the socket 200 from top to bottom. The isolation element 103 of the plug 100 will be inserted into the positioning groove 203 of the socket 200 through the opening 360 of the connection panel 300. As mentioned above, since the guide post 130 has the farthest extension distance, when the plug 100 is inserted into the socket 200, the guide post 130 will first enter the positioning hole 217, and then the isolation element 103 and the conductive terminal 120 will enter the positioning groove 203 and the socket connector 220 respectively.

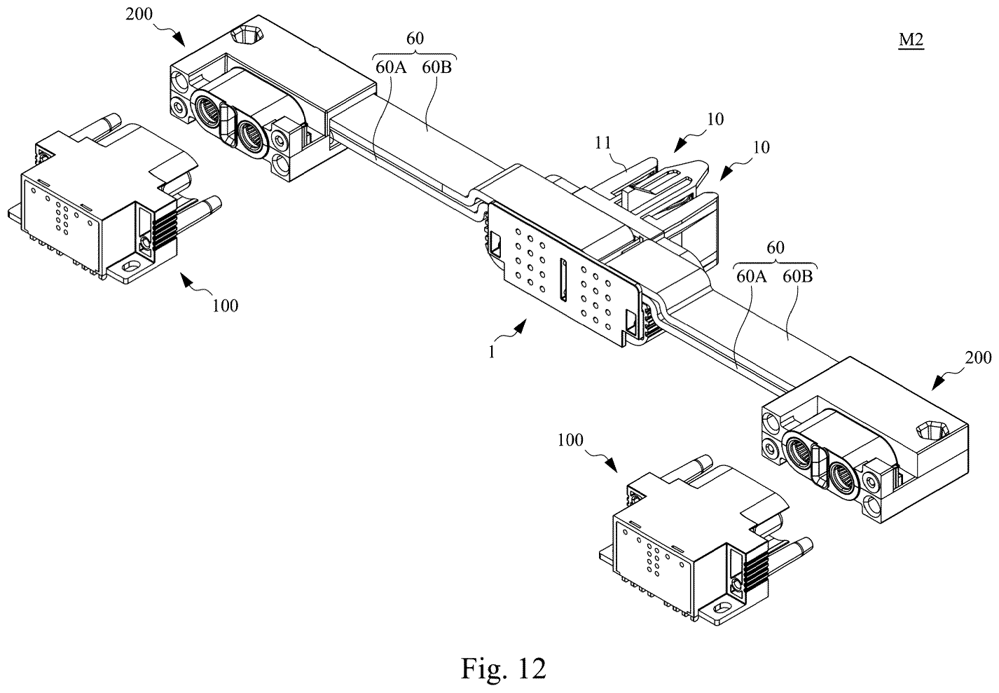

FIG. 12 is a perspective view of a connector assembly, in accordance with some embodiments of the present disclosure. FIG. 12 shows a bus connector assembly, also called connector assembly M2. It should be understood that the connector assembly M2 of FIG. 12 is similar to the connector assembly M1 discussed in connection with FIG. 1 to FIG. 11C. Therefore, similar components will be denoted by the same reference numerals and the related details will not be repeated. FIG. 12 to FIG. 18B will discuss the detailed structure of the connector assembly M2.

In the embodiment of FIG. 12, the connector assembly M2 includes a connector 1, a plurality of conductive strip groups 60, a plurality of sockets 200, and a plurality of plugs 100. That is, the connector component M2 has two conductive strip groups 60, which are electrically connected to the connector 1 and extend toward two sides of the connector 1. On the other hand, the connector assembly M2 has two sockets 200 and two plugs 100, wherein each socket 200 is electrically connected to a corresponding conductive strip group 60, and each plug 100 is connected to a corresponding socket 200.

It should be understood that although not shown in FIG. 12, the connector assembly M2 also has the connection panel 300 and the circuit board 400 as shown in the connector assembly M1 of FIG. 1.

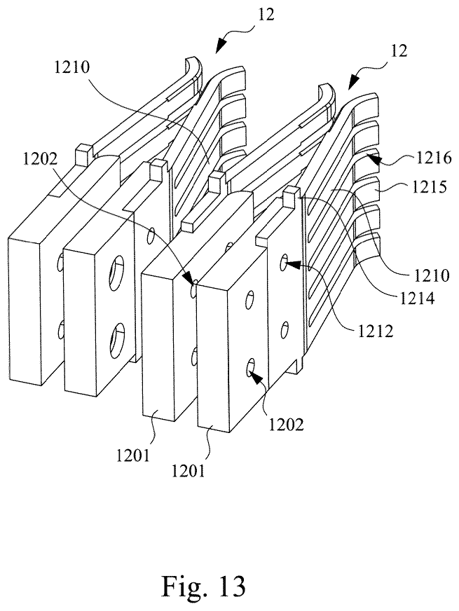

FIG. 13 is a perspective view of a conductive terminal structure, in accordance with some embodiments of the present disclosure, which will discuss the detailed structure of the conductive terminal structure 12 in the housing 11 of the connector 1 of FIG. 12.

Each of the conductive terminal structures 12 has a pair of conductive blocks 1201 and a pair of spring clips 1210, wherein each spring clip 1210 is disposed on a corresponding conductive block 1201. In some embodiments, the conductive blocks 1201 of each conductive terminal structure 12 are separated from each other.

Similarly, the conductive block 1201 may have a plurality of holes 1202, and the spring clip 1210 may have a plurality of holes 1212, wherein the holes 1212 of the spring clip 1210 may correspond to some of the holes 1202 of the conductive block 1201, thereby allowing a fixing element (such as a rivet or a screw) to pass through the holes 1212 of the spring clip 1210 and the holes 1202 of the conductive block 1201 to fix the spring clip 1210 and the conductive block 1201 together. In some embodiments, a groove is provided at the fixing position of the conductive block 1201 and the spring clip 1210, so that the outer surface of the spring clip 1210 after fixing is flush with the exposed outer surface of the conductive block 1201. In some embodiments, another portion of the holes 1202 of the conductive block 1201 do not correspond to the holes 1212 of the spring clip 1210, and these holes 1202 can be used to fix other components to the conductive block 1201.

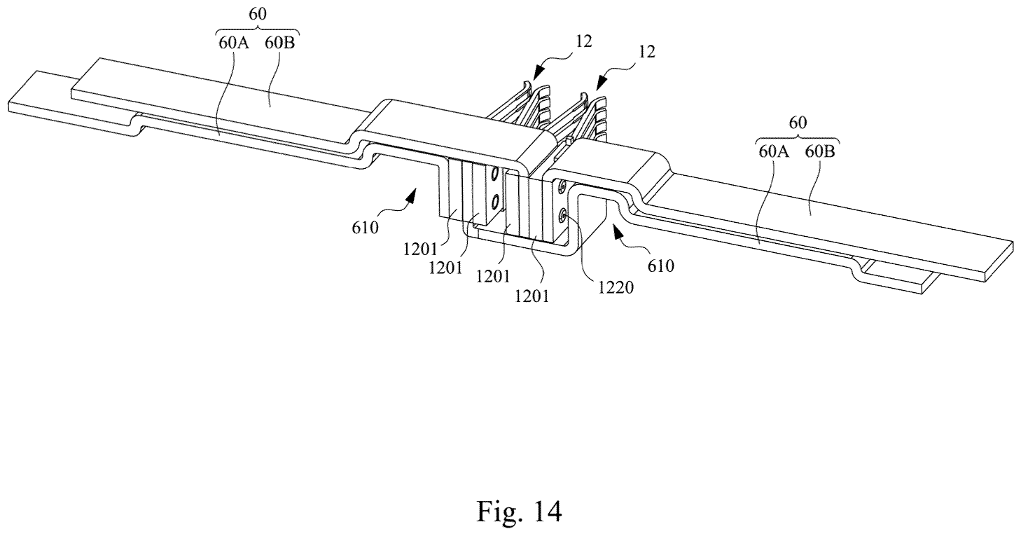

FIG. 14 is a perspective view of a conductive terminal structure and a conductive strip group, in accordance with some embodiments of the present disclosure. The connection relationship between the conductive terminal structure 12 and the conductive strip group 60 of the connector 1 of FIG. 12 will be discussed.

In some embodiments, two second conductive strips 60B may be first fixed to one of the conductive terminal structures 12. In detail, each of the second conductive strips 60B has a fixed portion fixedly connected to the conductive block 1201. In addition, the connection portions of the second conductive strips 60B and the conductive blocks 1201 are arranged alternately. In some embodiments, the fixed portion of the second conductive strip 60B is fixed to a surface of an outer side (a side away from another conductive terminal structure 12) of the corresponding conductive block 1201. The pair of conductive blocks 1201 of the conductive terminal structure 12 can be fixed and electrically connected to the two second conductive strips 60B at the same time; or fixed and electrically connected to only one of the two second conductive strips 60B respectively, but electrically isolated from the other one.

As mentioned in FIG. 13 and FIG. 2B, the conductive block 1201 of the conductive terminal structure 12 has a hole 1202, and the spring clip 1210 has a hole 1212. In some embodiments, the two second conductive strips 60B also have holes. Then, the fixing element 1220 can pass through the holes of the two second conductive strips 60B, the holes of the spring clip 1210 and the conductive block 1201 to fix the two second conductive strips 60B and their corresponding conductive terminal structures 12 together. In other words, the two second conductive strips 60B and the conductive terminal structure 12 are electrically connected to each other through contact. In some embodiments, the fixing element 1220 may be a rivet or a screw, or other suitable fixing elements.

Next, after the two second conductive strips 60B are fixed to one of the conductive terminal structures 12, the two first conductive strips 60A can be fixed to the other conductive terminal structure 12. The connection relationship between the first conductive strip 60A and the corresponding conductive terminal structure 12 is substantially the same as the connection relationship between the second conductive strip 60B and the corresponding conductive terminal structure 12, and thus will not be described in detail. In other embodiments, the two first conductive strips 60A may be fixed to one conductive terminal structure 12 first, and then the two second conductive strips 60B may be fixed to another conductive terminal structure 12.

In some embodiments, each of the conductive strip groups 60 can be bent to form a receiving space 610 on one side of the conductive terminal structure 12. The accommodating space 610 helps to fix the housing 11 of the connector 1 to other components.

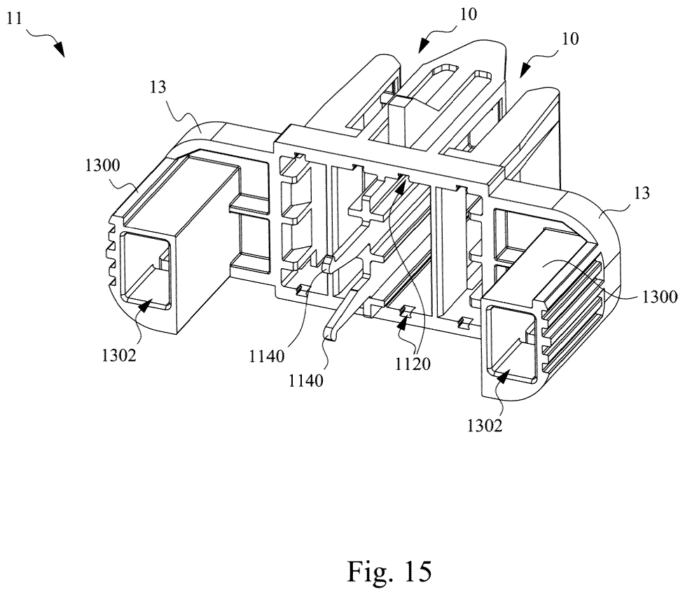

FIG. 15 is a perspective view of a housing of a connector, in accordance with some embodiments of the present disclosure, which will discuss the detailed structure of the housing 11 of the connector 1 of FIG. 12.

The housing 11 has wings 13 extending to opposite sides of the housing 11. In some embodiments, each wing portion 13 has a guiding structure 1300, wherein the guiding structure 1300 extends in a direction opposite to the slot 10 of the housing 11. In some embodiments, each guiding structure 1300 has a slot 1302. In some embodiments, the housing 11 also has two buckle structures 1140 extending in a direction opposite to the slots 10 of the housing 11. In addition, a plurality of grooves 1120 are also disposed in the housing 11.

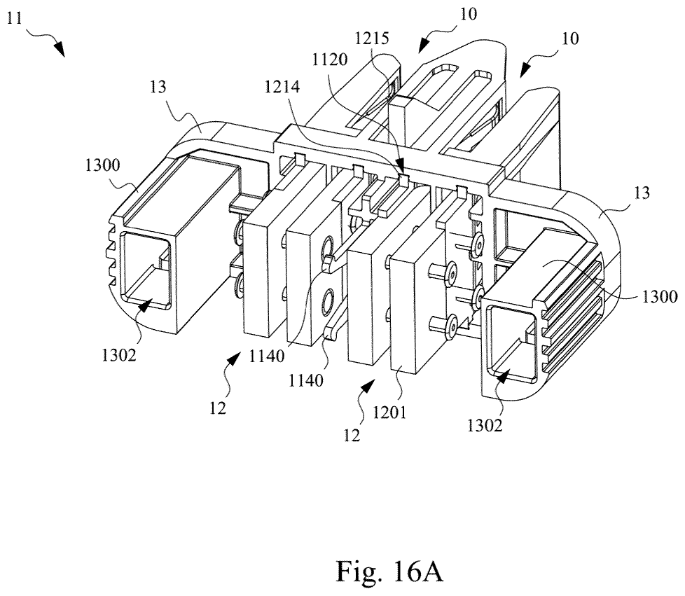

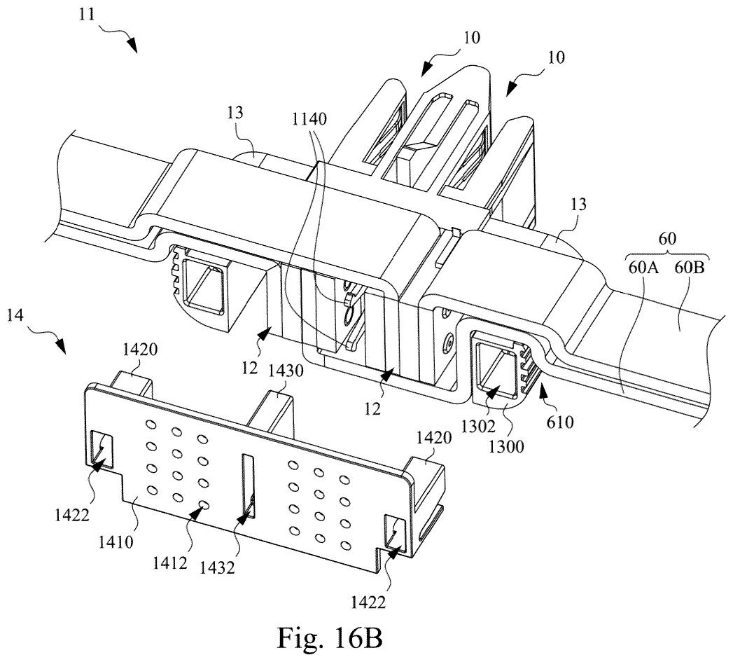

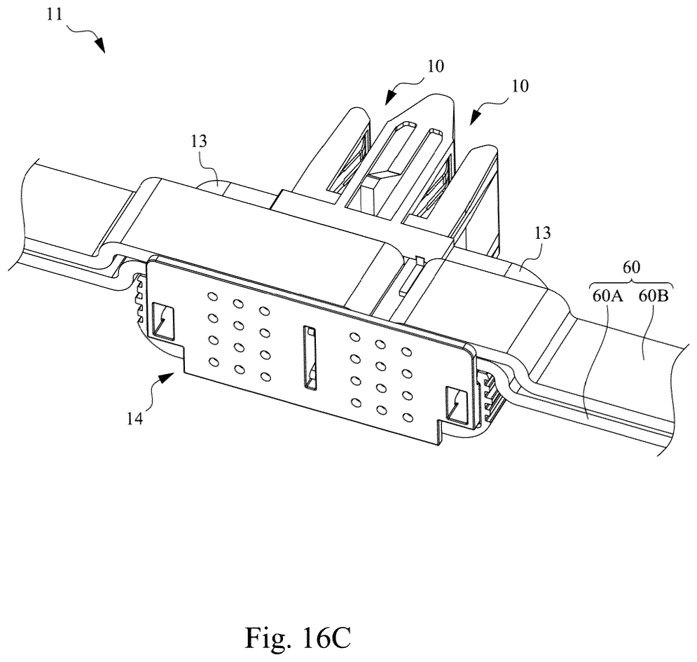

FIG. 16A, FIG. 16B and FIG. 16C are perspective views of a conductive terminal structure and a housing, in accordance with some embodiments of the present disclosure, which will discuss the connection relationship between the housing 11 and the conductive terminal structure 12 of the connector 1 of FIG. 12.

Please refer to FIG. 16A first. In some embodiments, the conductive strip group 60 may be installed on the conductive terminal structure 12 as discussed in FIG. 14, and then the conductive terminal structure 12 may be inserted into the housing 11. However, for the sake of ease of viewing, the conductive strip group 60 is not shown in FIG. 16A.

First, the two conductive terminal structures 12 are respectively inserted into the housing 11 along opposite sides of the buckle structure 1140 of the housing 11. As a result, the buckle structure 1140 will be located between the two conductive terminal structures 12, and the contact terminals 1215 of the springs clip 1210 of the conductive terminal structures 12 will extend to the position of the slots 10 of the housing 11.

In addition, the protruding structure 1214 of the spring clip 1210 of the conductive terminal structure 12 will be embedded in the groove 1120 of the housing 11. Such a design can limit the movement of the conductive terminal structure 12 on a plane perpendicular to the slot 10, so as to accurately fix the conductive terminal structure 12 on the housing 11.

Please refer to FIG. 16A and FIG. 16B. After the conductive terminal structure 12 is inserted into the housing 11, a cover plate 14 can be combined with the housing 11 to further fix the conductive terminal structure 12 in the housing 11.

As shown in FIG. 16B, after the conductive terminal structure 12 is inserted into the housing 11, the guide structure 1300 of the housing 11 will be disposed in the accommodation space 610 formed by the conductive strip group 60. From another perspective, the conductive strip group 60 can be designed to be bent along the shape of the guide structure 1300 of the housing 11, which helps to minimize the overall components.

On the other hand, the plate 14 includes a base 1410. In some embodiments, the base 1410 has a plurality of air holes 1412. Since the metal material of the conductive terminal structure 12 and the conductive strip group 60 in the housing 11 may cause high temperature when the conductive terminal structure 12 is energized, the air holes 1412 on the base 1410 will help dissipate heat to prevent the component temperature from being too high. The cover plate 14 further includes a guiding structure 1430 and a plurality of buckle structures 1420, which are connected to the base 1410 and extend from the base 1410 toward the housing 11. In some embodiments, the guiding structure 1430 has a slot 1432. In some embodiments, the buckle structure 1420 has a slot 1422.

Next, the cover plate 14 can be engaged with the housing 11. As shown in FIG. 16B and FIG. 16C, the buckle structure 1420 of the cover plate 14 is inserted into the slot 1302 of the guide structure 1300 of the housing 11. The guiding structure 1430 of the cover plate 14 is also inserted into the housing 11 and located between the two conductive terminal structures 12, so that the two conductive terminal structures 12 are electrically isolated. In addition, the buckle structure 1140 of the housing 11 is also inserted into the slot 1432 of the guide structure 1430 of the cover plate 14 to be engaged. In this way, the cover plate 14 can be tightly joined to the housing 11, so that the conductive terminal structure 12 is stably disposed in the housing 11.

In some embodiments, the connector 1 may have only one slot 10, and the two spring clips 1210 of the conductive terminal structure 12 are respectively fixed to the corresponding conductive blocks 1201, and are independent and electrically isolated from each other. The first conductive strip 60A and the second conductive strip 60B are respectively fixed and electrically connected to the corresponding conductive block 1201, and extend toward two sides of the connector 1.

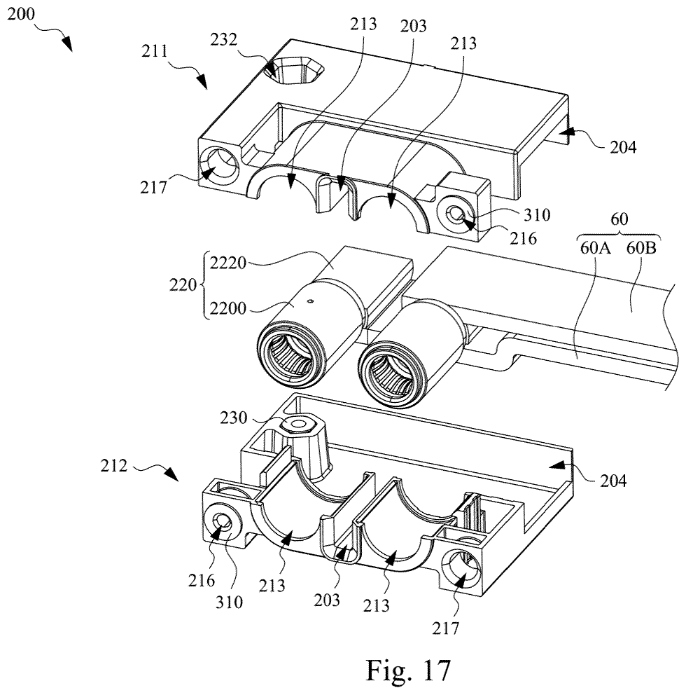

FIG. 17 is a perspective view of a conductive strip assembly and a socket, in accordance with some embodiments of the present disclosure, which will discuss the connection relationship between the conductive strip group 60 and the socket 200 of FIG. 12.

In some embodiments, the socket 200 has a socket housing 210 and a plurality of socket connectors 220. In some embodiments, each socket 200 has two socket connectors 220. The two socket connectors 220 are arranged to be aligned in the left-right direction. In some embodiments, the socket connector 220 may include copper, copper alloy, or similar conductive materials.

In some embodiments, each socket connector 220 has a main body portion 2200 and a conductive plate 2220 that are interconnected. The main body portion 2200 and the conductive plate 2220 may be an integrally formed structure. The conductive plate 2220 of one socket connector 220 contacts the upper surface of the first conductive strip 60A and is electrically connected thereto. On the other hand, the conductive plate 2220 of the other socket connector 220 contacts the lower surface of the second conductive strip 60B and is electrically connected thereto, wherein the conductive plate 2220 of the other socket connector 220 is also located on the upper surface of a portion of the first conductive strip 60A. However, the portion of the first conductive strip 60A may be covered with an insulating film or an insulating member so that the conductive plate 2220 of the other socket connector 220 does not make electrical contact with the first conductive strip 60A.

The socket housing 210 includes an upper housing 211 and a lower housing 212. In some embodiments, after the upper housing 211 and the lower housing 212 are assembled, an alignment groove corresponding to the shape of the main body 2200 of the socket connector 220 is formed to position the socket connector 220 in the socket housing 210. In detail, each of the upper housing 211 and the lower housing 212 has two alignment slots 213, wherein the alignment slots 213 have a substantially semicircular profile. When the upper housing 211 is combined with the lower housing 212, the alignment slot 213 of the upper housing 211 and the corresponding alignment slot 213 of the lower housing 212 will merge to form a circular receiving groove, and the socket connector 220 with a cylindrical structure can be positioned in the circular receiving groove.

On the other hand, the upper housing 211 and the lower housing 212 respectively have a positioning groove 203, wherein the positioning groove 203 has a narrow and long profile. When the upper housing 211 is combined with the lower housing 212, the positioning groove 203 of the upper housing 211 and the corresponding positioning groove 203 of the lower housing 212 will be combined to form a long and narrow groove body.

Furthermore, the upper housing 211 and the lower housing 212 each have a receiving space 204, wherein the receiving space 204 has a narrow and long profile. When the upper housing 211 is combined with the lower housing 212, the accommodating space 204 of the upper housing 211 and the corresponding accommodating space 204 of the lower housing 212 will be merged to form a narrow and long groove, and the conductive plate 2220 of the socket connector 220, a portion of the first conductive strip 60A and a portion of the second conductive strip 60B will be positioned in this narrow and long groove.

In some embodiments, the upper housing 211 and the lower housing 212 can be combined with each other through a buckle structure. In addition, a nut 230 may be provided in the housing of the lower housing 212, and a screw hole 232 may be provided in the housing of the upper housing 211, and the position of the screw hole 232 of the upper housing 211 corresponds to the nut 230 of the lower housing 212. Therefore, after the upper housing 211 and the lower housing 212 are combined, a screw can be used to lock the nut 230 of the lower housing 212 through the screw hole 232 of the upper housing 211. In this way, the upper housing 211 and the lower housing 212 can be firmly combined together.

In some embodiments, the socket housing 210 has a plurality of locking holes 216 and a plurality of positioning holes 217 in the direction of the mating surface of the socket 200. In some embodiments, the limiting element 301 is installed in the locking hole 216. In some embodiments, the socket housing 210 can be relatively movably connected to a connection panel 300 as discussed above, and the socket housing 210 has a floating space relative to the connection panel 300.

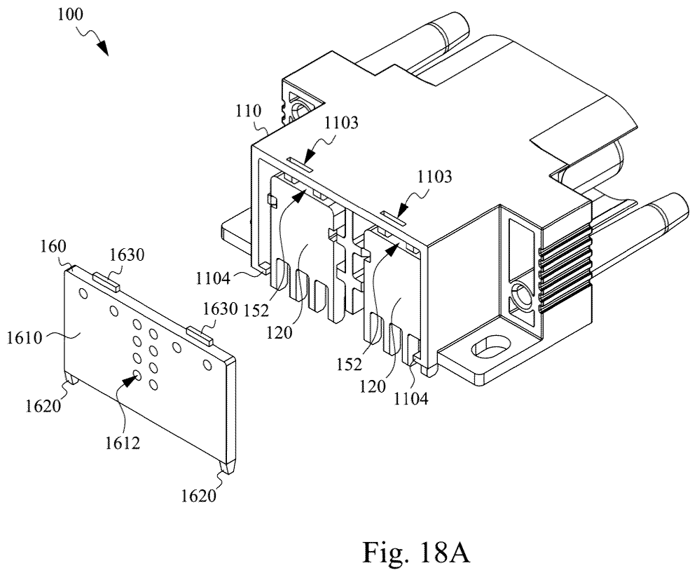

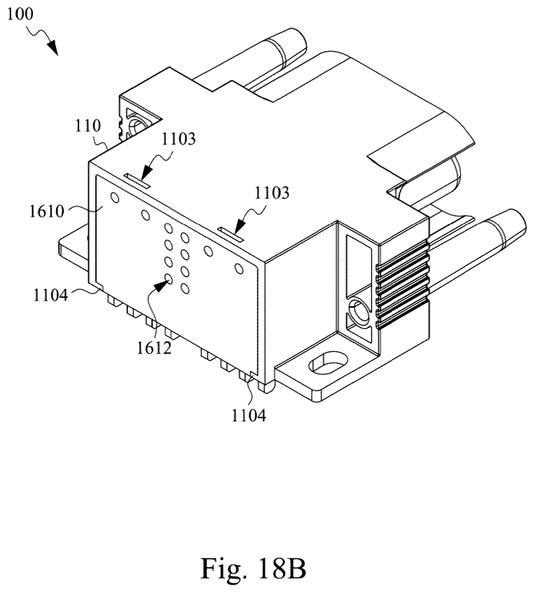

FIG. 18A and FIG. 18B are perspective views of a plug and a circuit board, in accordance with some embodiments of the present disclosure, and the detailed structure of the plug 100 of FIG. 12 will be discussed.

Refer to FIG. 18A. In some embodiments, the plug 100 includes a plug housing 110 and a plurality of conductive terminals 120 located inside the plug housing 110. In some embodiments, the conductive terminal 120 may be first mounted on a circuit board (such as the circuit board 400 described above), and then the conductive terminal 120 may be inserted into the receiving space 152 of the plug housing 110.

In some embodiments, the plug housing 110 also includes a plurality of grooves 1103 that are connected to the accommodating space 152. The plug housing 110 also includes a plurality of protrusion structures 1104.

After the conductive terminal 120 is inserted into the plug housing 110, a cover plate 160 can be combined with the plug housing 110 to further fix the conductive terminal 120 in the plug housing 110.

Please refer to the cover plate 160, which includes a base 1610. In some embodiments, the base 1610 has a plurality of air holes 1612. During the period when the conductive terminals 120 are powered, the conductive terminals 120 in the plug housing 110 may generate high temperatures due to conducting large currents. The air holes 1612 on the base 1610 will help dissipate heat to prevent the component temperature from being too high. The cover plate 160 further includes a plurality of buckle structures 1620 located at the lower edge of the base 1610, and a plurality of buckle structures 1630 located at the upper edge of the base 1610.

Next, the cover plate 160 can be engaged with the plug housing 110. As shown in FIGS. 18A to 18B, the buckle structures 1620 of the cover plate 160 are first pressed against the inner edges of the protruding structures 1104 of the plug housing 110. Next, the cover plate 160 is pushed toward the plug housing 110, and the buckle structures 1630 are respectively engaged in the grooves 1103 of the plug housing 110. In this way, the cover plate 160 can be tightly joined to the plug housing 110, and the conductive terminal 120 can be stably disposed in the plug housing 110.

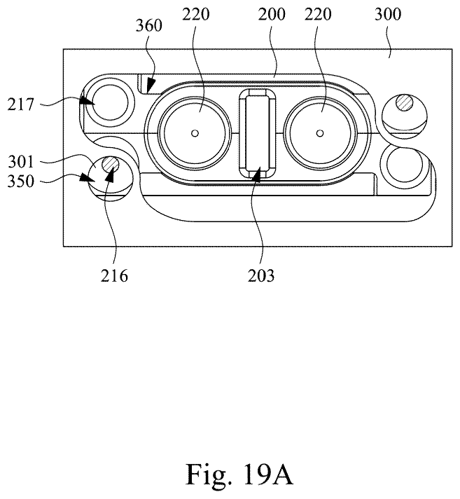

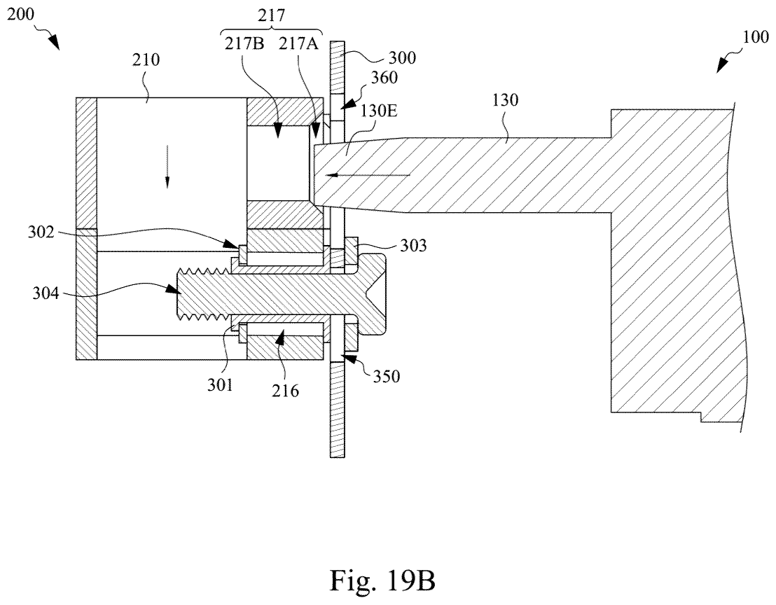

FIG. 19A and FIG. 19B are perspective views of the relative relationship among a plug, a socket and a connection panel, in accordance with some embodiments of the present disclosure, and will discuss a schematic diagram of plugging the plug 100 into the socket 200 through the opening 360 of the connection panel 300. FIG. 19A is a plan view of the socket 200 and the connection panel 300, and FIG. 19B is a cross-sectional view of the socket 200, the connection panel 300, and the plug 100.

Please refer to FIGS. 19A and 19B. In some embodiments, the socket 200 and the connection panel 300 may have errors during the installation process, or tolerances during the manufacturing process of the conductive strip group 60 and the socket 200 may cause the socket 200 and the connection panel 300 to be offset. Taking the example of FIG. 19A and FIG. 19B as an example, with the position of the connection panel 300 as a reference, the socket 200 is offset upward relative to the connection panel 300, further causing the positioning hole 217 of the socket 200, the socket connector 220 and the positioning groove 203 to be offset upward. Generally speaking, the deviation of the socket will cause misalignment during the subsequent engagement process between the plug and the socket. The design disclosed in the present invention may solve this problem.

Please refer to FIG. 19B. When the plug 100 moves toward the socket 200, since the guide post 130 of the plug 100 has the longest extension distance, the guide post 130 of the plug 100 will first pass through the opening 360 of the connection panel 300 and move toward the positioning hole 217 of the socket 200. Although the deviation of the socket 200 will cause the positioning hole 217 and the guide post 130 to be not completely aligned, the end 130E of the guide post 130 can contact the surface of the first portion 217A of the positioning hole 217. As mentioned above, since the first portion 217A of the positioning hole 217 has a gradually narrowing profile, the inclined surface will help guide the guide post 130 into the positioning hole 217. In addition, the gradually narrowing profile of the end portion 130E of the guide post 130 also helps guide the guide post 130 into the positioning hole 217 of the socket 200.

As mentioned above, since the screw 304 has floating space in the opening 350 of the connection panel 300, and the limiting element 301 has floating space in the locking hole 216, this will allow the socket 200 to move relative to the connection panel 300. Therefore, as the guide post 130 of the plug 100 enters the positioning hole 217 of the socket 200, the guide post 130 will generate a downward force on the socket 200, so that the socket 200 is moved and adjusted to an ideal position.

In some embodiments, the floating space of the guide post 130 between the openings 360 is larger than the floating space of the screw 304 within the opening 350, which allows for greater tolerance for inserting the guide post 130 into the positioning hole 217.

FIG. 19A only discusses an example in which the socket 200 and the connection panel 300 are offset in one direction. However, it should be understood that the embodiments of the present disclosure may be applicable to situations where the socket 200 and the connection panel 300 are offset in different directions. In addition, the embodiments of the present disclosure may be applicable to a situation where the socket 200 and the plug 100 are offset.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A connector assembly, comprising:
a socket comprising:
a plurality of socket connectors;
a socket housing covering the socket connectors and comprising a locking hole; and
a limiting element disposed in the locking hole of the socket housing, and the limiting element comprising a first floating space in the locking hole;
a connection panel comprising a first opening, and the socket housing being fixed to the connection panel; and
a screw comprising a screw head and a screw pin, the screw pin passing through the first opening of the connection panel and being locked to the limiting element, wherein the screw pin has a second floating space in the first opening.

2. The connector assembly of claim 1, further comprising:
a plug configured to be coupled to the socket, wherein the plug has a plug housing and a plurality of conductive terminals located in the plug housing, wherein the conductive terminals pass through the connection panel and are respectively connected to the socket connectors of the socket.

3. The connector assembly of claim 2, wherein the socket housing further comprises a positioning hole, and the plug housing further comprises a guide post configured to be inserted into the positioning hole.

4. The connector assembly of claim 3, wherein the positioning hole of the socket housing has a first part and a second part connected to each other, the first part is closer to the connection panel than the second part, and the first part has a gradually narrowing width toward an inside of the socket housing.

5. The connector assembly of claim 3, wherein a tip of the guide post of the plug housing has a gradually narrowing profile.

6. The connector assembly of claim 3, wherein the connection panel has a second opening separated from the first opening, wherein the conductive terminals and the guide post of the plug housing pass through the second opening of the connection panel, and wherein the second opening is larger than the first opening.

7. The connector assembly of claim 1, wherein the limiting element comprises:
a main body portion disposed in the locking hole of the socket housing; and
a first end and a second end respectively located at two ends of the main body, wherein a diameter of the main body and a diameter of the second end are smaller than a diameter of the locking hole, a diameter of the first end is larger than the diameter of the locking hole, and the first end abuts against a first surface of the socket housing.

8. The connector assembly of claim 7, further comprises a C-shaped ring, wherein the C-shaped ring abuts against a second surface of the socket housing, the C-shaped ring is set on the main body of the limiting element, and the C-shaped ring is located between the second surface of the socket housing and the second end of the limiting element.

9. The connector assembly of claim 1, further comprising a washer which abuts against a side of the connection panel away from the socket housing, wherein the screw pin of the screw passes through the washer.

10. A connector housing comprises:
a housing having a locking hole;
a connection panel having a first opening; and
a limiting mechanism having two ends for clamping the connection panel and at least a portion of the housing between the two ends,
wherein the limiting mechanism is movable within a first preset range relative to the housing, and/or the limiting mechanism is movable within a second preset range relative to the connection panel.

11. The connector housing of claim 10, wherein the two ends of the locking hole have a first hole and a second hole on a first surface and a second surface of the housing, respectively, the first hole is arranged facing the first opening such that the first surface abuts against one side of the connection panel, one end of the two ends of the limiting mechanism has a size larger than a size of the first opening and abuts against another side of the connection panel, and another end of the two ends of the limiting mechanism has a size larger than a size of the second hole and abuts against the second surface of the housing.

12. The connector housing of claim 11, wherein the limiting mechanism comprises a limiting element and an auxiliary plate, the limiting element includes a first end, a second end, and a main body located between the first end and the second end, the first end is located on the first surface, and the auxiliary plate is detachably disposed on the main body and located between the second end and the second surface.

13. The connector housing of claim 12, wherein the main body is smaller than the locking hole, such that the main body and the locking hole are movable relatively within the first preset range.

14. The connector housing of claim 10, wherein the limiting mechanism comprises a screw having a screw head and a screw pin, the screw pin passes through the first opening and is smaller than the first opening, such that the screw pin and the first opening are movable relatively within the second preset range.

15. The connector housing of claim 14, wherein the limiting mechanism further comprises a washer located between the screw head and one side of the connection panel.
